(19) United States
(12) Patent Application Publication
(10) Pub. No.: US 2003/0193824 A1
(43) Pub. Date: Oct. 16, 2003

(54) Semiconductor memory device

(75) Inventors: Yasuhiko Tsukikawa, Hyogo (JP); Takuya Ariki, Hyogo (JP); Susumu Tanida, Hyogo (JP); Yukiko Maruyama, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/319,521

(22) Filed: Dec. 16, 2002

(30) Foreign Application Priority Data
Apr. 11, 2002 (JP) 2002-109462(P)

(51) Int. Cl. G11C 11/401

(52) U.S. Cl. 365/149

(57) ABSTRACT

A memory cell is formed of a sense access transistor for data sensing, a restore access transistor for data restoration and a memory capacitor for data storage. Sense access transistor couples the memory capacitor to a sense bit line according to a signal on a sense word line. The restore access transistor couples the memory capacitor to a restore bit line provided separate from the sense bit line according to a signal on a restore word line. Electric charges in the memory capacitor are transferred to a sense amplifier through the sense bit line and sense data in a sense amplifier is transferred to original memory capacitor through a restore amplifier and the restore access transistor. Output signal lines of the sense amplifier are electrically isolated from the sense and restore bit lines. Thereby, it is possible to reduce the access time of a semiconductor memory device.

### BACKGROUND OF THE INVENTION

1. Field of the Invention

The present invention relates to a semiconductor memory device, and particularly to a semiconductor memory device with a memory cell structure storing data in a capacitor in the form of electric charges. More particularly, the present invention relates to a configuration and a memory cell layout for achieving high speed access to a dynamic type memory cell.

2. Description of the Background Art

FIG. 38 is a diagram showing a configuration of a conventional DRAM (Dynamic Random Access Memory) cell. In FIG. 38, a DRAM cell MC includes: a memory capacitor MQ for storing information; and an access transistor MT rendered selectively conductive in response to a signal on a word line WL to couple memory capacitor MQ to a bit line BL. In FIG. 38, access transistor MP is formed of an N-channel MOS transistor (insulated gate field effect transistor).

Memory capacitor MQ receives a prescribed voltage at a main electrode (cell plate electrode) thereof and stores electric charges corresponding to storage information in a storage node SN.

A complementary bit line /BL is arranged in parallel to bit line BL. No memory cell is arranged at an intersection between complementary bit line /BL and word line WL. Bit lines BL and /BL are provided with an bit line equalize circuit BLEQ activated in response to an equalize instruction signal EQ for equalizing bit lines BL and /BL to a prescribed voltage, and a sense amplifier SA activated in response to a sense amplifier activation signal SE for amplifying and latching potentials on bit line BL and /BL. Sense amplifier SA is normally formed of cross-coupled N-channel MOS transistors and cross-coupled P-channel MOS transistors and drives, when activate, bit lines BL and /BL to power supply voltage and ground voltage levels according to memory cell storage data.

Such a configuration is called “a folded bit line configuration” that bit lines BL and /BL are arranged in pair on one side of a sense amplifier in parallel to each other, and memory cell data is read out onto one bit line (BL) and a reference voltage in sensing operation is applied by the other bit line (/BL).

FIG. 39 is a signal waveform diagram representing operations in data reading from a memory cell shown in FIG. 38. Brief description will now be applied of data read operation on the memory cell shown in FIG. 38 below with reference to FIG. 39.

In a standby state, equalize instruction signal EQ is in an active state (at H level) and bit line equalize circuit BLEQ is in an active state to equalize bit lines BL and /BL to a voltage level of an intermediate voltage (VDD/2). Sense amplifier SA is in an inactive state.

When a row select instruction (ACT) is externally applied, equalize instruction signal EQ is deactivated to cease an equalize operation on bit lines BL and /BL. In this state, bit lines BL and /BL are in a floating state at equalize voltage level.

In memory cell capacitor MQ, a voltage level SN (H) at a storage node SN, in storing H level data, is power supply voltage level, while in storing L level data, voltage level SN (L) at storage node SN is ground voltage level.

Then, word line WL is selected according to an address signal and rises in voltage level. In accordance with the rise in voltage on word line WL, access transistor MP turns conductive to transmit electric charges accumulated in memory capacitor MQ onto bit line BL.

Since bit line BL is set at intermediate voltage level, when access transistor MT turns conductive, potential SN (H) at storage node SN storing H level data lowers while potential SN (L) at storage node SN storing L level data increases. In FIG. 39, there is shown voltage changes when H level data and L level data are transmitted on bit line BL. Complementary bit line /BL maintains the intermediate voltage as shown with a broken line in FIG. 39.

When sense amplifier activation signal SE is activated, sense amplifier SA amplifies a small potential difference between bit lines BL and /BL (performs a sense operation) to drive the voltages on bit lines BL and /BL to power supply voltage VDD and ground voltage level according to storage data. After the sensing operation of sense amplifier SA, voltages SN (L) and SN (H) at storage nodes SN are each driven by sense amplifier through bit line BL (/BL) to restore original voltage levels.

Then, a column select gate (not shown) is brought into a conductive state according to a column address signal and a voltage latched by sense amplifier SA is transmitted to an output buffer circuit through an internal data bus.

Since electric charges accumulated in memory capacitor MQ is discharged onto bit line BL by a read operation, storage data in memory capacitor MQ is once destructed (destructive readout is performed). Therefore, word line WL is maintained in an active state for a while after the sensing operation is completed, to restore a potential at storage node SN of memory cell capacitor MQ through access transistor MT (a restore operation is performed).

After reading out memory cell data, for example, a precharge instruction (PRG) is applied, and the selected word line WL is driven into a non-selected state to turn access transistor MT into non-conductive state. Then, sense amplifier SA is deactivated and equalize circuit BLEQ is activated to again equalize bit lines BL and /BL to the prescribed voltage, thus completing one memory cycle.

FIG. 40 is a signal waveform diagram showing operations in writing data to memory cell MC shown in FIG. 38. Brief description will be given of a data writing operation below with reference to FIG. 40.

In data writing as well, word line WL is selected, followed by activation of sense amplifier SA, and sensing and latching operations on data in memory cell MC, as in data reading.

When a data write instruction (WRITE) is applied externally, a column select operation is performed according to a column address signal to activate a column select signal CSL. A column select gate (not shown) turns conductive according to column select signal CSL to allow write data to be transmitted onto bit lines BL and /BL. Potentials on bit lines BL and /BL change according to the write data and, in response, a potential at storage node SN of a selected memory cell changes according to the write data.

Word line WL maintains its selected state till after completion of writing of write data to storage node SN of the selected memory cell. To non-selected memory cells connected to selected word line WL, no write data is transmitted and only a restore operation is performed to restore voltages SN (H) and SN (L) at storage nodes SN to power supply voltage and ground voltage levels, respectively.

In completion of the data write operation, selected word line WL is driven into a non-selected state according to precharge instruction (PRG) and sense amplifier activation signal SE is deactivated to deactivate sense amplifier SA. Then, equalize instruction signal EQ is activated to drive bit lines BL and /BL to original intermediate voltage level.

The DRAM cells are each formed of one access transistor and one. memory capacitor and is smaller in number of components and in occupancy area as compared with an SRAM (Static Random Access Memory). Therefore, the DRAM has been generally used in wide applications as a large storage capacity memory such as a main memory.

In the DRAM, however, there is performed a dynamic operation to equalize bit lines to a prescribed voltage level in standby state and a time period of the order of 70 ns (nanoseconds) is typically required for a read (or write) cycle. The reasons why a long write/read cycle is required in DRAM are as follow.

As one of the reasons, a restore operation is performed after a sense operation and a word line can be deactivated only after the sense and restore operations are completed. Therefore, a cycle time is longer than the sum of a sensing time and a restoring time. As a second reason, a bit line pair is required to be equalized at a prescribed voltage level after completion of the restore operation, in order to be ready for the next read/write cycle. As shown in FIG. 41, therefore, an actual cycle time, tcyc, is given by the sum of a sensing time tsen from application of a row select instruction till completion of a sense operation, a restoring time tres for writing original data to a memory cell after the sense operation, and an equalize time teq till bit lines are equalized to an original prescribed voltage level after completion of the restore operation (after a word line is driven to be in an inactive state). A third reason is such that it is required to equalize bit lines BL and /BL, fully swung to power supply voltage VDD and ground voltage GND, to the intermediate voltage level, which causes the equalization to require a long time.

A series of such operations as word line selection, a sense operation, a restore operation and an equalize operation is called a random access cycle and the total time of such series of operations is called a random access cycle time (or cycle time).

Since in the DRAM, a random access cycle time is 70 ns, longer as compared with that in the SRAM, a problem arises that high speed access could not achieved. Especially, in random access, an operating speed is on the order 15 MHz, causing a problem that the DRAM cannot be applied in a processing system operating in an operating cycle of the order of, for example, 100 MHz.

### SUMMARY OF THE INVENTION

It is an object of the present invention to provide a semiconductor memory device capable of reducing a random access cycle time.

A semiconductor memory device according to a first aspect of the present invention includes: a plurality of memory cells, arranged in rows and columns, each having a capacitor storing information and first and second access transistors coupled commonly to one electrode of the capacitor; a plurality of first word lines, arranged corresponding to respective memory cell rows, each coupled to the first access transistors of memory cells on a corresponding row to drive first access transistors of memory cells on the corresponding row into a conductive state when selected; a plurality of second word lines, arranged corresponding to respective memory cell rows, each coupled to second access transistors of memory cells on a corresponding row to drive the second access transistors of the memory cells on the corresponding row into a conductive state when selected; a plurality of first bit lines, arranged corresponding to memory cell columns, each coupled to first access transistors of memory cells on a corresponding column to transfer data transmitted through a first access transistor of a memory cell on the corresponding column; a plurality of second bit lines, arranged corresponding to memory cell columns, each coupled to second access transistors of memory cells on a corresponding column to transfer write data to a memory cell on the corresponding column; and a plurality of sense amplifiers, arranged corresponding to the plurality of first bit lines, each for sensing and amplifying data on a corresponding first bit line when activated.

The semiconductor memory device according to the first aspect of the present invention further includes a plurality of restore circuits, arranged corresponding to the plurality of second bit lines and to the plurality of first sense amplifiers, each for latching amplified data of at least a corresponding first sense amplifier to drive a corresponding second bit line according to a latch signal when activated.

A semiconductor memory device according to a second aspect of the present invention includes: a plurality of active regions each having a prescribed width and arranged consecutively extending in a column direction; a plurality of first bit lines arranged in parallel to the active regions; a plurality of second bit lines arranged in parallel to the active regions so as to establish a prescribed sequence with the first bit lines; a plurality of first word lines arranged in a direction intersecting with the active regions; a plurality of second word lines arranged in a direction intersecting with the active regions in a prescribed sequence with the plurality of first word lines; a plurality of first connection conductors, arranged in a column direction at prescribed spacings in correspondence to the respective active regions, each for electrically coupling a corresponding active region with a corresponding first bit line; a plurality of second connection conductors, arranged in a column direction at prescribed spacings in correspondence to the respective active regions, each for electrically coupling a corresponding active region with a corresponding second bit line; and a plurality of memory capacitors each having a storage electrode conductor arranged corresponding to the active region between the first and second connection conductors in the column direction and electrically coupled to a corresponding active region. The storage electrode conductors each constitute a part of a storage node for storing data of a memory cell.

In each of the active regions, a first access transistor is formed in a region intersecting with a first word line and a second access transistor is formed in a region intersecting with a second word line. Each memory cell is formed of first and second access transistors and a capacitor having a storage electrode conductor arranged between the first and second transistors.

By forming one memory cell with one capacitor and two access transistors, using a first bit line for sensing memory cell data and using a second bit line for restoring memory cell data, a sense operation and a restore operation can be performed in an interleaved fashion. Therefore, after completion of a sense operation, a different row can be selected without waiting completion of a restore operation, and a restore time and an equalize time can be hidden externally to reduce a cycle time.

Furthermore, by arranging active regions consecutively extending in a column direction, an occupation area of a memory cell formation region arranging memory cells can be reduced and layout of memory cells is made easier. Moreover, by arranging first and second bit lines in parallel to the active regions in layout, connection of the first and second bit lines with the active regions is made easier. Thus, memory cells can be arranged in all intersection regions between word lines and bit lines with a construction of one memory cell formed of one capacitor and two access transistors, thereby achieving a high density arrangement of memory cells.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram showing a configuration of a main part of a semiconductor memory device according to a first embodiment of the present invention;

FIG. 2 is a signal waveform diagram representing operations of the semiconductor memory device shown in FIG. 1;

FIG. 3 is a diagram showing cycle times of a semiconductor memory device according to the present invention and a conventional semiconductor memory device;

FIG. 4 is a diagram schematically showing a configuration of a part related to row selection of the semiconductor memory device according to the first embodiment of the present invention;

FIG. 5 is a diagram schematically showing an example of a configuration of a part generating row related control signals of the semiconductor memory device according to the first embodiment of the present invention;

FIG. 6 is a signal waveform diagram representing operations of a row related control signal generating section shown in FIG. 5;

FIG. 7 is a diagram schematically showing a configuration of a main part of a semiconductor memory device according to a second embodiment of the present invention;

FIG. 8 is a diagram showing a configuration of a main part of a semiconductor memory device according to a third embodiment of the present invention;

FIG. 9 is a diagram schematically showing a configuration of a first modification of the third embodiment of the present invention;

FIG. 10 is a diagram schematically showing a configuration of a second modification of the third embodiment of the present invention;

FIG. 11 is a diagram showing a specific configuration of a restore amplifier and select gates shown in FIG. 10;

FIG. 12 is a diagram schematically showing a configuration of a main part of a semiconductor memory device according to a fourth embodiment of the present invention;

FIG. 13 is a diagram showing an example of a configuration of a part generating a bit line isolation instruction signal shown in FIG. 12;

FIG. 14 is a diagram schematically showing a main part of a semiconductor memory device according to a fifth embodiment of the present invention;

FIG. 15 is a diagram showing a configuration of a part generating a bit line isolation instruction signal shown in FIG. 14;

FIG. 16 is a signal waveform diagram representing operations of a circuit shown in FIG. 15;

FIG. 17 is a diagram showing a main part of a semiconductor memory device according to a sixth embodiment of the present invention;

FIG. 18 is a signal waveform diagram representing operations of a semiconductor memory device shown in FIG. 17;

FIG. 19 is a diagram schematically showing an example of a configuration of a part generating control signals shown in FIG. 17;

FIG. 20 is a diagram showing a main part of a semiconductor memory device according to a seventh embodiment of the present invention;

FIG. 21 is a signal waveform diagram representing operations of a semiconductor memory device shown in FIG. 20;

FIG. 22 is a diagram showing a main part of a semiconductor memory device according to an eighth embodiment of the present invention;

FIG. 23 is a signal waveform diagram representing operations of the semiconductor memory device shown in FIG. 22;

FIG. 24 is a diagram schematically showing a configuration of a memory mat in a semiconductor memory device according to a ninth embodiment of the present invention;

FIG. 25 is a diagram showing a configuration of a part of a sense/restore amplifier arranged at an end of a memory mat;

FIG. 26 is a diagram showing a configuration of a main part of a semiconductor memory device according to a tenth embodiment of the present invention;

FIG. 27 is a signal waveform diagram representing operations of the semiconductor memory device shown in FIG. 26;

FIG. 28 is a diagram schematically showing an example of a configuration of a part generating control signals shown in FIG. 26;

FIG. 29 is a diagram showing a modification of the tenth embodiment of the present invention;

FIG. 30 is a diagram schematically showing a layout of a memory array according to an eleventh embodiment of the present invention;

FIG. 31 is a diagram schematically showing a sectional structure of a memory cell shown in FIG. 30;

FIG. 32 is a diagram schematically showing a sectional structure of a part of connection conductors shown in FIG. 30;

FIG. 33 is a diagram showing a layout of a memory cell array according to an twelfth embodiment of the present invention;

FIG. 34 is a diagram schematically showing arrangement of sense/restore amplifiers in the memory cell layout shown in FIG. 33;

FIG. 35 is a diagram schematically showing a layout of a memory cell array according to a thirteenth embodiment of the present invention;

FIG. 36A is a diagram schematically showing a layout of memory cells according to a fourteenth embodiment, and FIG. 36B is a diagram schematically showing arrangement of sense/restore amplifiers corresponding to the layout shown in FIG. 36A;

FIG. 37A is a diagram schematically showing a layout of memory cells according to a fifteenth embodiment of the present invention, and FIG. 37B is a diagram schematically showing arrangement of sense/restore amplifiers corresponding to the layout shown in FIG. 37A;

FIG. 38 is a diagram schematically showing a configuration of a memory array section of a conventional DRAM;

FIG. 39 is a signal waveform diagram representing operations in data reading of the DRAM shown in FIG. 38;

FIG. 40 is a signal waveform diagram representing operations in data writing of the DRAM shown in FIG. 38; and

FIG. 41 is a diagram showing a cycle time of a conventional DRAM.

### DESCRIPTION OF THE PREFERRED EMBODIMENTS

First Embodiment

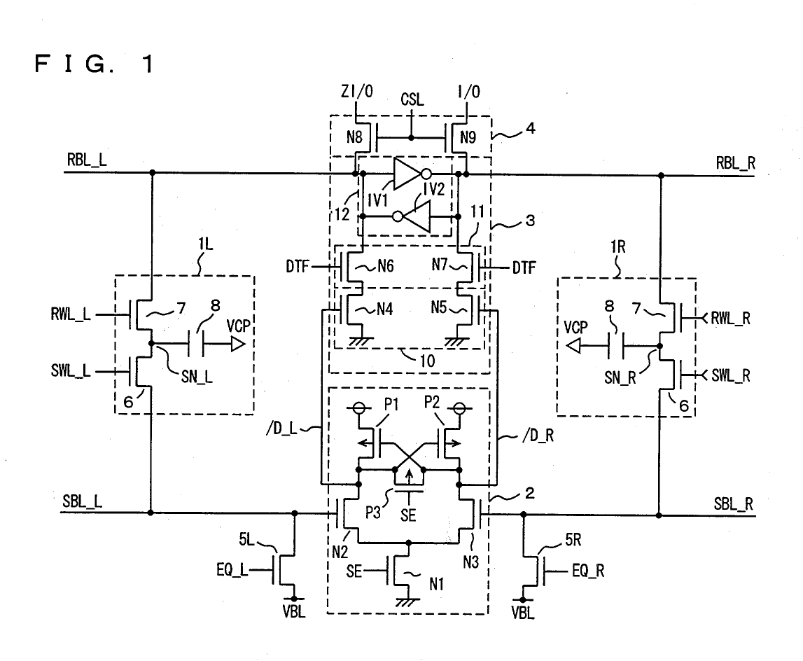

FIG. 1 is a diagram showing a configuration of a main part of a semiconductor memory device according to a first embodiment of the present invention. Memory cells 1 are arranged in rows and columns in the open bit line configuration. In FIG. 1, there are representatively shown two memory cells 1R and 1L. To memory cell 1R, there are provided a sense bit line SBL_R and a restore bit line RBL_R and to memory cell 1L, there are provided a sense bit line SBL_L and a restore bit line RBL_L.

Sense bit lines SBL_R and SBL_L are coupled to sense amplifiers 2. Sense amplifier 2, in an active state, differentially amplifies potentials on sense bit lines SBL_R and SBL_L to output the output signals thereof onto sense output lines /D_R and /D_L. Sense output lines /D_R and /SD_L are electrically isolated from sense bit lines SBL_R and SBL_L. Therefore, sense bit line SBL_R and SBL_L only transmit data of a selected memory cell, and data amplified by sense amplifier 2 is not transmitted onto sense bit lines SBL_R and SBL_L.

Equalize transistors 5R and 5L are provided to respective sense bit lines SBL_R and SBL_L. Equalize transistor 5R turns conductive, in response to activation of equalize instruction signal EQ_R, to transmit a precharge voltage VBL onto sense bit line SBL_R. Equalize transistor 5L turns conductive, in response to activation of equalize instruction signal EQ_L, to transmit a precharge voltage VBL onto sense bit line SBL_L.

Memory cells IR and IL each includes: a memory capacitor 8 storing information in the form of electric charges; a sense access transistor 6 rendered conductive, in response to a signal on a sense word line SWL (SWL_R and SWL_L), to connect corresponding memory capacitor 8 to corresponding sense bit line SBL (SBL_R and SBL_L); and a restore access transistor 7 rendered conductive, in response to a signal on a restore word line RWL (RWL_R and RWL_L), to connect corresponding memory capacitor 8 to sense bit line RBL (RBL_R and RBL_L).

That is, memory cell 1 (1R and 1L) is formed of one memory capacitor and two access transistors.

Sense access transistor 6 and restore access transistor 7 are coupled, respectively, to sense word line SWL and restore word line RWL, which are driven into a selected state at different timings from each other.

Sense amplifier 2 includes: an N-channel MOS transistor N1 rendered conductive, on activation of sense amplifier activation signal SE, to activate a sense operation of sense amplifier 2; an N-channel MOS transistor N2, connected between sense output line /D_R and MOS transistor N1, having a gate connected to sense bit line SBL_L; an N-channel MOS transistor N3 connected between sense output line /D_R and MOS transistor N1, and having a gate connected to sense bit line SBL_R; a P-channel MOS transistor P1 connected between a power supply node and sense output line /D_L, and having a gate connected to sense output line /D_R; a P-channel MOS transistor P2 connected between a power supply node and sense output line /D_R, and having a gate connected to sense output line /D_L; and a P-channel MOS transistor P3 rendered conductive, on deactivation of sense amplifier activation signal SE, to electrically short circuit sense output lines /D_L and /D_R.

The sense input nodes of sense amplifier 2 are coupled in a high impedance state to sense bit lines SBL_L and SBL_L and differentially amplifies a potential difference between sense bit lines SBL_L and SBL_R without exerting an influence on the potentials on sense bit lines SBL_L and SB_R.

Since the gate and drain of each of MOS transistor P1 and P2 are interconnected with each other, MOS transistors P1 and P2 operate as diodes, when MOS transistor P3 is conductive, to equalize sense output lines /D_L and /D_R to power supply voltage level.

Restore amplifier 3 includes: a differential stage 10 differentially amplifying signals on sense output line /D_L and /D_R; a transfer gate 11 rendered conductive, in activation of transfer instruction signal DTF, to transmit output signals of differential stage 10; and latch circuit 12 for amplifying and latching signals transmitted through transfer gate 11.

Differential stage 10 includes: an N-channel MOS transistor N4 having a gate connected to sense output line /D_L; and an N-channel MOS transistor N5 having a gate connected to sense output line /D_R. MOS transistors N4 and N5 each have a source coupled to ground node.

Differential stage 10 performs an amplify operation without exerting an influence on output signals of sense amplifier 2. Sense amplifier 2 is required merely to drive gate capacitances of MOS transistors N4 and N5 of differential stage, and therefore, a driving ability of sense amplifier 2 can be smaller, which makes a layout area of sense amplifier 2 smaller.

Transfer gates 3 includes N-channel MOS transistors N6 and N7 provided corresponding to respective MOS transistors N4 and N5 and rendered conductive in activation of a transfer instruction signal DTF.

Latch circuit 12 includes inverters IV1 and IV2 arranged in anti-parallel to each other. The term “anti-parallel” indicates a configuration in which an input of each inverter is connected to an output of the other inverter. That is, the output of inverter IV1 is coupled to the input of inverter IV2 and the output of inverter IV2 is coupled to the input of inverter IV1. Latch circuit 12 is an inverter latch and amplifies and latches complementary signals transmitted through transfer gate 11. Latch nodes of latch circuit 12 is coupled to restore bit lines RBL_R and RBL_L.

Column select gate 4 includes N-channel MOS transistors N8 and N9 connected to latch nodes of latch circuit 12, or restore bit lines RBL_L and RBL_R and having gates receiving column select signal CSL. Restore bit line RBL_R is connected to internal data line I/O through MOS transistor N9 and restore bit line RBL_L is connected to internal data line ZI/O through MOS transistor N8.

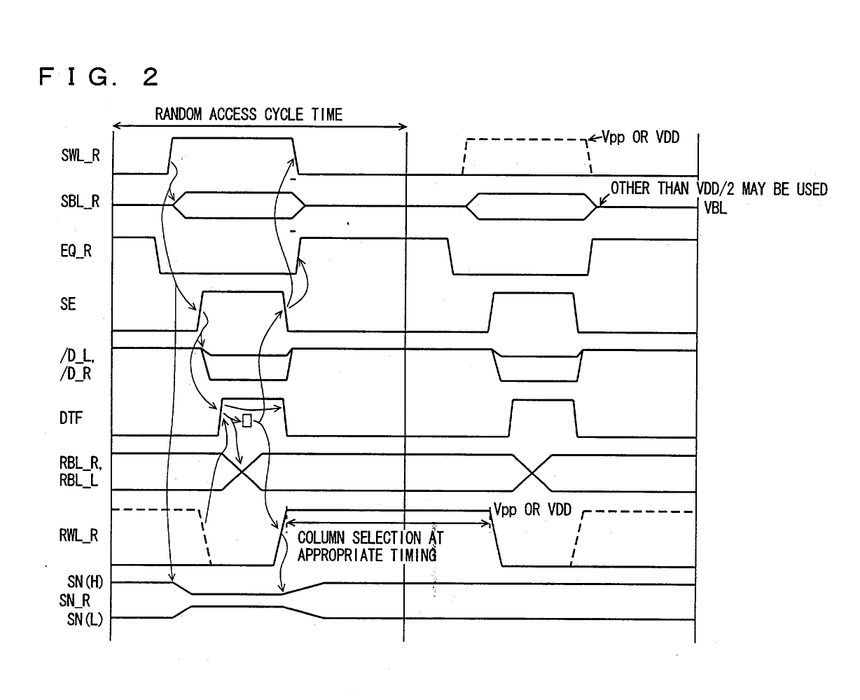

FIG. 2 is a signal waveform diagram representing operations in data reading of the configuration shown in FIG. 1. In FIG. 2, there is shown operating waveforms in data reading in a case where memory cell 1R of memory block in the right side is selected. Description will be below given of operations of the configuration shown in FIG. 1 with reference to FIG. 2.

Equalize instruction signals EQ_R and EQ_L are both at H level in standby state and sense bit lines SBL_R and SBL_L are equalized to a prescribed voltage VBL level. Equalize voltage VBL may be a voltage level at 1/2 times power supply voltage VDD, may be either higher or lower than intermediate voltage VDD/2, and is sufficient to be a voltage in a region where a sense sensitivity of sense amplifier 2 is the best.

When an access cycle starts, equalize instruction signal EQ_R is deactivated according to an applied address signal to complete an equalize operation of sense bit line SBL_R. Equalize instruction signal EQ_L maintains its active state.

Then, sense word line SWL_R is selected according to the address signal to has a voltage level thereof raised. A select voltage level of sense word line SWL_R may be power supply voltage VDD level or alternatively, may be a boosted voltage Vpp level higher than power supply voltage VDD.

In a case where a voltage level on a selected word line is power supply voltage VDD, there is no need to generate a boosted voltage, thereby allowing reduction in consumed current. Furthermore, in a case where a voltage level on a selected word line is the boosted voltage Vpp level, a driving ability of access transistor 6 of memory cell 1 can be larger, thereby achieving high speed transmission of accumulated electric charges in memory capacitor 8 to corresponding sense bit line SBL. In a case where a select voltage of a word line is a boosted voltage level, however, it takes a longer time for a voltage on a selected word line to rise up to the boosted voltage level. In consideration of these factors, therefore, an optimal voltage level is set as a select voltage level on sense word line so as to enable the sensing operation to start at the fastest timing.

When sense word line SWL_R is selected to have a voltage level thereon raised, sense access transistor 6 in memory cell 1R turns conductive to transmit electric charges accumulated in storage node SN_R of memory cell capacitor 8 onto sense bit line SBL_R. Sense bit line SBL_R is connected to the gate of MOS transistor N3 of sense amplifier 2. A voltage level on sense bit line SBL_R is a voltage level changing according to electric charges read out from memory capacitor and sense bit line SBL_R merely transmits a small amplitude signal.

Then, when sense word line SWL_R is selected and electric charges are transmitted onto sense bit line SBL_R, sense amplifier activation signal SE is activated to cause MOS transistor N1 to be conductive and sense amplifier performs a sense operation. Voltage levels on sense output lines /D_L and /D_R are changed from power supply voltage, which is a precharge level, by MOS transistors N2 and N3. Changes in potential on sense output lines /D_L and /D_R produced via driving by MOS transistors N2 and N3 are amplified by MOS transistors P1 and P2 at high speed. Responsively, one of sense output lines /D_L and /D_R is discharged to ground potential level, while maintaining the other sense output line at high level, according to a potential on sense bit line SBL_R. Here, the reason why the high level voltages on sense output lines /D_L and /D_R are lower than power supply voltage VDD level is that MOS transistors N2 and N3 are both in on state to drive currents.

When sense amplifier activation signal SE is activated and voltage levels on sense output lines /D_L and /D_R are made definite at high level and low level, then transfer instruction signal DTE is activated and kept in an active state for a prescribed period to cause transfer gate 3 to be conductive. In response to this, latch nodes of latch circuit 2 are driven by differential stage 10 according to potentials on sense output lines /D_L and /D_R and potential levels on the latch nodes of latch circuit 12, or potential levels on restore bits lines RBL_L and RBL_R are amplified by inverters in latch circuit 12 to change to H level and L level. Potential levels on restore bits lines RBL_L and RBL_R are latched by latch circuit 12.

When transfer instruction signal DTF is activated and the potentials on restore bits lines RBL_L and RBL_R become definite, restore word line RWL_R is activated to cause restore access transistor 7 of a selected memory cell to be conductive. Responsively, a signal at power supply voltage or ground voltage level is transmitted onto storage node SN_R of capacitor 8 to restore a potential on storage node SN_R to an original potential level. Here, in FIG. 2, there are shown potential SN (H) when storage node SN_R stores data at H level and potential SN (L) when storage node SN_R stores data at L level.

Restore word line RWL_R in a selected state is deactivated prior to activation of transfer instruction signal DTF. The deactivated restore word line is a restore word line having been selected according an address signal in the previous cycle.

Sense amplifier activation signal SE is deactivated after data transfer instruction signal DTF is activated and output signals of sense amplifier 2 are transferred to restore circuit 12. When sense amplifier activation signal SE is deactivated, sense word line SWL_R is deactivated, and then, equalize instruction signal EQ_R is activated to restore a potential on sense bit line SBL_R to original equalize voltage VBL level.

Restore word line RWL_R maintains its active state and column select operation can be performed at an appropriate timing during a period when restore word line RWL_R is in an active state.

Specifically, after a sense operation is completed and amplified data of sense amplifier 2 is transferred to latch circuit, a sense word line can be driven into a non-selected state and thereby another sense word line can be selected. In a conventional DRAM, there is a necessity for performing a series of operations of activation of a restore word line, a sense operation, a restore operation, deactivation of a selected word line and an equalize operation on bit lines in this order. According to the first embodiment, after activation of a selected word line and a sense operation are performed sequentially, deactivation of a selected word line and equalization of bit lines can be performed substantially simultaneously in parallel to each other. The sequence of deactivation of a selected sense word line and equalization on sense bit lines is not restrictive and any may be performed first. If equalization on sense bit lines is performed after deactivation of a selected word line, the equalization can be performed without exerting an adverse influence on accumulated electric charges in storage node SN of a selected memory cell.

On the other hand, if a selected sense word line is deactivated after equalization on sense bit lines, equalize voltage VBL is transmitted to storage node SN of a memory cell. In this case, however, since a voltage having swung to the full is transmitted to a selected memory cell by latch circuit 12 through restore bit line RBL, and since restore word line RWL maintains its selected state even after deactivation of a selected sense word line SWL, memory cell data can be restored with correctness. In this case, an equalize timing can be made faster to thereby advance a selecting timing of a sense word line in the next cycle (since equalization on bit lines can be completed at an advanced timing). Furthermore, deactivation of a selected sense word line and equalization on sense bit lines may be substantially simultaneously performed. In this case, control timings can be set with ease.

Read data from a memory cell is merely transferred onto a sense bit line, but output signals of sense amplifier 2 is not transmitted to sense bit lines. Therefore, an amplitude of a voltage on a sense bit line is small, thereby enabling equalization of sense bit lines to be completed in a short time.

Data transferred to latch circuit 12 according to data transfer instruction signal DTE is transmitted onto restore bit lines RBL_R and RBL_L. After latch data in latch circuit 12 is transmitted onto restore bit lines RBL_R and RBL_L, restore word line RWL_R is activated. Activation level (select voltage level) of restore word line RWL may be even power supply voltage VDD, or may be a boosted voltage higher than power supply voltage VDD. When a voltage level on restore word line RWL is boosted voltage, a driving ability of restore access transistor 7 can be large to thereby allow latch data of latch circuit 12 to be transferred to sense node SN_R at high speed for restoration. Furthermore, a signal at the power supply voltage level can be transmitted to storage node SN_R of memory capacitor 8 without a loss by a threshold voltage across restore access transistor 7. In a case of the boosted voltage, it takes time to drive selected restore word line to the boosted voltage. On the other hand, in a case where activation level (select voltage level) on a restore word line is power supply voltage, there is no need to use a boosted voltage, thereby achieving reduction in consumed current and further achieving decrease in time required for raising a restore word line to the select voltage level. In this case, since H level of restore bit line RBL (RBL_R or RBL_L) is power supply voltage VDD, H level of storage data in a memory cell becomes a voltage level lower than power supply voltage VDD by threshold voltage Vth of restore access transistor 7. Though no problem arises especially in data access, a data retention characteristic is degraded since the amount of accumulated electric charges in memory cell capacitor 8 decreases. Therefore, in consideration of these factors, activation level of a restore word line is set to an optimal voltage level.

Restore word line RWL_R is deactivated prior to activation of data transfer instruction signal DTF in the next cycle.

In a case where sense word line SWL_R is active upon activation of restore word line RWL_R, there arises a period during which restore bit line RBL_R and sense bit line SBL_R are electrically short-circuited. In this case, however, a period when sense word line SWL_R and restore word line RWL_R are both in selected-state is short, and sense bit line SBL_R is reliably equalized to equalize voltage VBL by equalize transistor 5R after deactivation of sense word line SWL_R. Restore bit line RBL_R is also held at power supply voltage or ground voltage level by latch circuit 12 and memory cell 1R has the storage data certainly restored.

In consideration of the above operation sequence, as for the sensing operation related side, only activation of a sense word line and a sense operation are performed sequentially and therefore, no consideration is necessary to be given to a restore operation. Thus, a cycle time can be shorter greatly by a time required for restoration. Furthermore, since deactivation of a sense word line and equalization of sense bit lines can be substantially simultaneously performed in parallel to each other, which can further reduce the cycle time. In addition, since a voltage on a sense bit line SBL changes only over a small potential, a time for equalization can be shorter compared with a configuration in which the bit line voltage is swung to the full in amplitude.

On the restoring operation related side, a restore state is maintained through all the period till data transfer instruction signal DTF is activated in the next cycle after data transfer from a sense amplifier to a restore amplifier according to data transfer instruction DTF. Therefore, a sense operation and an equalize operation are not required, and a cycle time can be reduced greatly. In restore amplifier 3, latch circuit 12 constantly performs a latch operation, restore bit lines RBL_L and RBL_R are set at H level or L level at all times and no equalize operation on restore bit lines is performed. Therefore, a cycle time for restoration can be greatly reduced.

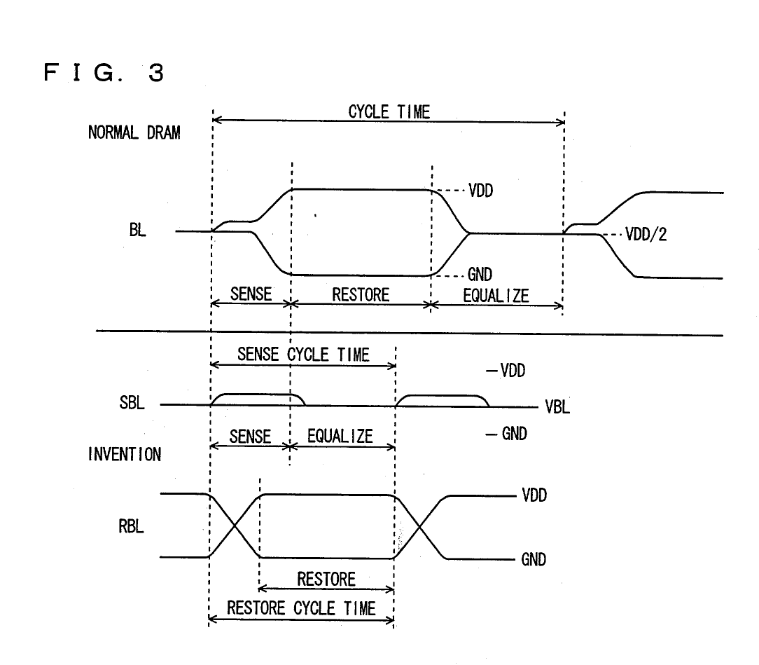

FIG. 3 is a diagram showing a change in voltage on bit lines in a normal DRAM and the inventive DRAM. In the normal DRAM, as shown in FIG. 3, a bit line has a voltage level changed each time a sense operation, a restore operation and an equalize operation are each performed. Therefore, in the normal DRAM, a cycle time is given by the sum of a sense period, a restore period and an equalize period. In an equalize period, bit lines BL are required to be equalized from voltage levels of power supply voltage VDD and ground voltage GND to the same voltage level at intermediate voltage of VDD/2.

According to the configuration of the present invention, on the other hand, voltages on sense bit lines SBL change only from the equalize voltages in accordance with storage data in a memory cell and do not fully swing to power supply voltage VDD or ground voltage GND. Therefore, in a case where a cycle time is given by the sum of a sense time and an equalize time as well, an equalize operation is only to equalize a small potential difference. Thus, an equalize time for sense bit lines can be greatly reduced, as compared with an equalize time in the normal DRAM.

In restore bit lines RBL, voltages thereon are fully swung in amplitude to power supply voltage VDD and ground voltage GND and no equalize time is provided. Data access is performed during a restore period. In other words, in data access, column select gate 4 is made conductive by column select signal SCL to connect latch nodes of latch circuit 12, or restore bit lines RBL_R and RBL_L to internal data lines I/O and ZI/O, so that any of data reading and writing can be done.

Data access is merely required to be performed in a period of a selected state of restore word line RWL (RWL_R). Therefore, in FIG. 2, there is no need to perform both a row select operation and a column select operation in one random access cycle time. A column select operation may be performed in a cycle subsequent to a random access cycle in which a row select operation is performed. Inside of DRAM, column and row select operations can be performed in parallel to each other. In this case, row access to perform row selection and column access to perform column selection may be simultaneously designated, or row access and column access may be externally designated in a time division multiplexed manner, similarly to a normal DRAM. In this case, if there exists latency indicating a prescribed time between application of the designation of data reading and external data outputting, high speed data access can be achieved by performing row access and column access internally in a pipelined fashion.

Sense amplifier 2 are connected directly to sense bit lines SBL_R and SBL_L and restore circuit 4 are also connected directly to restore bit lines RBL_L and RBL_R. Therefore, signals can be transmitted at high speed, thereby achieving high speed sensing and restoring operations.

As for the arrangement of the memory cells, one column of memory cells is connected to each of pairs of sense bit lines and of restore bit lines, which are arranged on either sides of restore circuit 4 and sense amplifier 2. Sense amplifier 2 senses data on sense bit line onto which memory cell data is read out with the other sense bit line used as a reference bit line and restore circuit 4 drives restore bit lines arranged on both sides thereof according to output data of sense amplifier 2. Such a configuration of bit lines is called “open bit line configuration.”

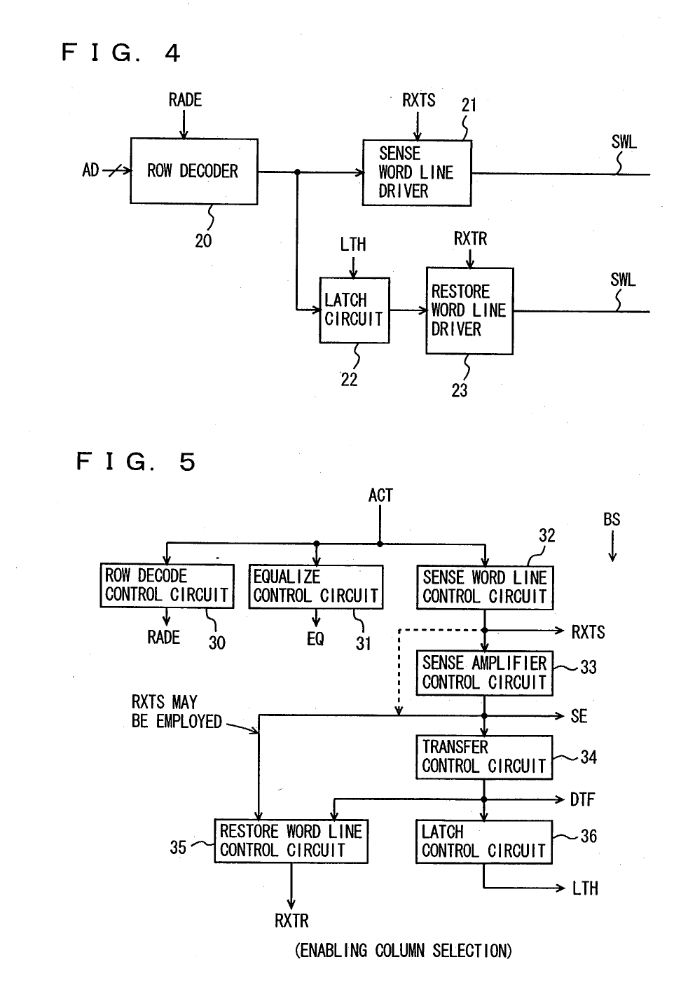

FIG. 4 is a diagram schematically showing a configuration of a part associated with row selection of the semiconductor memory device according to the first embodiment of the present invention. In FIG. 4, a row selection circuitry includes: a row decoder 20 activated in response to activation of a row address decode enable signal RADE to decode an address signal AD applied for generating a word line designation signal when activated; a sense word line driver 21 activated in response to activation of a sense word line drive timing signal RXTS, to drive sense word line SWL into selected state according to the word line designation signal from row decoder 20; a latch circuit 22 for latching an output signal of row decoder 20 in response to a latch instruction signal LTH; and a restore word line driver 23 activated in response to restore word line drive timing signal RXTR, to drive restore word line RWL into a selected state according to a latch signal of latch circuit 22.

Sense word line driver 21 shown in FIG. 4 is arranged corresponding to each sense word line SWL, and latch circuit 22 and restore word line driver 23 are provided corresponding to each restore word line RWL.

With latch circuit 22 provided, after restore word line driver 23 drives restore word line RWL into a selected state in response to activation of restore word line drive timing signal RXTR, sense word line SWL in the next cycle can be driven into the selected state according to a subsequent different address signal by sense word line driver 23.

Latch circuit 22 has only to be of any configuration, as far as it takes in and latches an output signal of row decoder 20 upon activation of the latch instruction signal. For example, it can be formed of a transmission gate operating in response to the latch instruction signal and an inverter latch for latching and outputting a signal transferred through the transmission gate.

FIG. 5 is a diagram schematically showing a configuration of circuitry for generating row related control signals of the semiconductor memory device according to the first embodiment of the present invention. In the configuration of the row related control circuit shown in FIG. 5, control signals associated with a sense word line are activated according to activation and deactivation of a row access instruction signal ACT. Row access instruction signal ACT may be generated in the form of one shot pulse with a prescribed time width when a row access instruction is applied or alternatively, may be a signal having its activation and deactivation controlled according to a row access instruction and a precharge instruction. A sense cycle time is determined by row access instruction signal ACT. Furthermore, as for the access sequence, a row access instruction and a column access instruction are simultaneously applied, or a row access instruction and a column access instruction may be applied in a time division multiplexed fashion.

In FIG. 5, a row related control circuit includes: a row decode control circuit 30 for activating row decode enable signal RADE in response to activation of row access instruction signal ACT; an equalize control circuit 31 for deactivating bit line equalize instruction signal EQ in response to activation of row access instruction signal ACT; a sense word line control circuit 32 for activating sense word line drive timing signal RXTS in response to row access instruction signal ACT; a sense amplifier control circuit 33 for activating sense amplifier activation signal SE in response to activation of sense word line drive timing signal RXTS; a transfer control circuit 34 for activating transfer instruction signal DTF in response to activation of sense amplifier activation signal SE to maintain the transfer instruction signal in the active state during a prescribed period; a restore word line control circuit 35 for generating restore word line drive timing signal RXTR in response to sense amplifier activation signal SE and transfer instruction signal DTF; and a latch control circuit 36 for generating latch instruction signal LTH kept in an active state during a prescribed period in response to activation of transfer instruction signal DTF.

Control circuits 30 to 33 are substantively formed of delay circuits and each activates signals RADE, RXTS and SE and deactivates equalize instruction signal EQ at prescribed timings in response to activation of row access instruction signal ACT.

Transfer control circuit 34 activates transfer instruction signal DTF in the form of a one shot pulse when a prescribed period elapses after activation of sense amplifier activation signal SE.

Restore word line control circuit 35 deactivates restore word line drive timing signal RXTR when a prescribed period elapses after activation of sense amplifier activation signal SE and activates restore word line drive timing signal RXTR when a prescribed period elapses after activation of transfer instruction signal DTF.

Sense word line drive timing signal RXTS may be applied to restore word line control circuit 35 instead of sense amplifier activation signal SE. A restore word line is deactivated after a sense word line is driven into selected state according to sense word line drive timing signal RXTS.

Latch control circuit 36 activates latch instruction signal LTH in response to activation of transfer instruction signal DTF to maintain latch instruction signal LTH in an active state during a prescribed period.

A sense access cycle time is defined by row access instruction signal ACT. When row access instruction signal ACT is deactivated, row decode enable signal RADE from row decode control circuit 30 is deactivated to deactivate row decoder 20.

Equalize control circuit 31 deactivates and maintain bit line equalize signal EQ in an inactive state for a prescribed period. Sense word line control circuit 32 activates and maintain sense word line drive timing signal RXTS in an active state for a prescribed period. Sense amplifier control circuit 33 activates/deactivates sense amplifier activation signal SE according to sense word line drive timing signal RXTS.

Alternatively, deactivation timings of output signals of control circuits 30, 32 and 33 and an activation timing of an output signal of equalize control circuit 31 may be determined by deactivation of row access instruction signal ACT.

A column interlock period is terminated by activation of restore word line drive timing signal RXTR to permit a column select operation internally. A period of column interlock may be determined by activation of transfer instruction signal DTF.

A bit line configuration is the open bit line configuration as shown in FIG. 1 and bit lines are arranged on both sides of sense amplifiers 2 and restore amplifiers 3. That is, memory cells are divided into a plurality of groups. In the where the row related control circuit shown in FIG. 5 is a main row control circuit provided commonly to the plurality of groups, a row related control signal for a corresponding memory cell group is generated in a local row related control circuit provided corresponding to each group, in accordance with a main row related signal from the main row related control circuit on the basis of a block select signal BS designating a memory cell group.

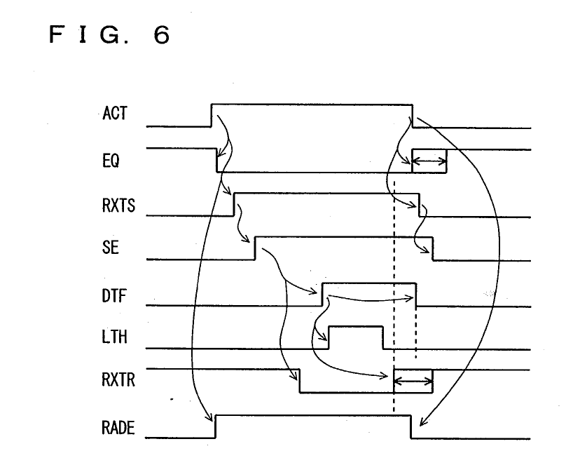

Alternatively, in the case where the row related control circuit shown in FIG. 5 is a local row related control circuit provided corresponding to each memory cell group, a local row related control circuit may be activated according to row access instruction signal ACT and block select signal BS to generate a row control signal for a corresponding memory cell group. Now, description will be given of operations of the row related control circuit shown in FIG. 5 with reference to a timing diagram shown in FIG. 6. In the following description, no description is given of the combination with block select signal BS. This is because the way of generating row related control signals are different depending on a configuration of a row related control circuit, as described above. Row related control signals to a selected memory cell group are activated/deactivated in a sequence described below.

When row access instruction signal ACT is activated, equalize instruction signal EQ from equalize control circuit 31 is deactivated and row decoder enable signal RADE from decode control circuit 30 is also activated. Responsively, row decoder 20 shown in FIG. 4 is activated to take in an applied address to perform a decode operation. An equalize operation is terminated in a selected memory cell group (block) in response to deactivation of equalize instruction signal EQ.

Sense word line control circuit 32 activates restore word line drive timing signal RXTS when a prescribed period elapses after deactivation of equalize instruction signal EQ. Sense amplifier control circuit activates sense amplifier activation signal SE when a prescribed period elapses after activation of sense word line drive timing signal RXTS. Sense amplifier 2 shown in FIG. 1 performs a sense operation in response to activation of sense amplifier activation signal SE to generate signals corresponding to storage data in a selected memory cell onto sense output lines /D_L and /D_R.

When sense amplifier activation signal SE is activated, restore word line control circuit 35 deactivates restore word line drive timing signal RXTR in order to prepare for a restore operation on selected memory cell data. Restore word line RWL in selected state is driven into inactive state.

After deactivation of restore word line drive timing signal RXTR, transfer control circuit 34 maintains transfer instruction signal DTF in active state for a prescribed period in response to activation of sense amplifier activation signal SE. Transfer control circuit 34 is formed, for example, of a one-shot pulse generating circuit. When transfer instruction signal DTF is activated, transfer gate 11 in the restore amplifier shown in FIG. 1 turns conductive and data amplified by sense amplifier 2 is transferred to latch circuit 12.

On the other hand, when transfer instruction signal DTF is activated, latch control circuit 36 activates and maintain latch instruction signal LTH in an active state for a prescribed period. The latch circuit 22 shown in FIG. 4 takes in and latches output signals of row decoder 24 in response to activation of latch instruction signal LTH. A restore word line designation signal designating a restore word line to be selected in the next cycle is latched by a latch operation of latch circuit 22. At this time, restore word line drive timing signal RSTR is still in an inactive state to maintain restore word line RWL in inactive state.

When latch transfer instruction signal LTH is deactivated to bring latch circuit 22 into a latching state, restore word line control circuit 35 activates restore word line drive timing signal RXTR in response to activation of transfer instruction signal DTF. What is required for activation of restore word line drive timing signal RXTR is that a signal potential on restore bit lines is made definite. Restore word line drive timing signal RXTR may be activated in activation of transfer instruction signal DTF, or may be activated after transfer instruction signal DTF is deactivated and a transfer operation is completed.

Restore word line driver 23 shown in FIG. 4 is activated according to activation of restore word line drive timing signal RXTR, to drive a corresponding restore word line into selected state according to a restore word line designation signal latched in latch circuit 22.

When the restore word line is activated, row access instruction signal ACT is deactivated, equalize instruction signal EQ from equalize control circuit 31 is activated and sense word line drive timing signal RXTS is deactivated. Activation of equalize instruction signal EQ may be done at the same time with deactivation of sense word line drive timing signal RXTS. Equalize instruction signal EQ may be activated when sense word line drive timing signal RXTS is in active state, or may be activated after sense word line drive timing signal RXTS is deactivated.

Since sense output lines of sense amplifier 2 are electrically isolated from sense bit lines, a correct restore operation can be performed if a transfer operation for output signals of sense amplifier 2 to restore amplifier 3 is completed regardless of a timing relationship between activation of equalize instruction signal EQ and deactivation of sense word line drive timing signal RXTS.

Then, when sense word line drive timing signal RXTS is deactivated, sense amplifier activation signal SE is deactivated. Deactivation of sense amplifier activation signal SE may be performed in response to activation of equalize instruction signal EQ.

When row access instruction signal ACT is deactivated, row decoder enable signal RADE is also deactivated to return row decoder 20 to standby state.

Restore word line control circuit 35 can be formed of a first delay circuit delaying sense amplifier activation signal SE by a prescribed time; a second delay circuit delaying transfer instruction signal DTF by a prescribed time; and a set/reset flip-flop reset in response to activation of an output signal of the first delay circuit and set in response to activation of an output signal of the second delay circuit 2.

Furthermore, transfer control circuit 34 for generating transfer instruction signal DTF my be so configured as to activate and hold transfer instruction signal DTF in active state for a prescribed period in response to deactivation of restore word line drive timing signal RXTR.

By using latch circuit 22 shown in FIG. 4 to latch word line designation signal outputted by row decoder 20, activation/deactivation of sense word lines SWL and restore word lines RWL can be individually performed.

Note that as configurations of sense word line. driver 21 and restore word line driver 23, a word line driver used in a normal DRAM can be employed. That is, a configuration activated in response to word line drive timing signals RXTS and RXTR for driving sense word line SWL and restore word line RWL in accordance with the word line designation signal, may be used for a configuration of word line drivers 21 and 23. Alternatively, as a construction of word line drivers 21 and 23, a configuration may be adopted in which word line drive timing signals RXTS and RXTR are transferred to corresponding sense word line SWL and restore word line RWL, respectively, according to a word line designation signal.

In the case of the configuration shown in FIG. 4, row decoder 20 can be provided commonly to a sense word line and a restore word line, thereby achieving decrease in circuit occupation area.

Furthermore, alternatively, a sense row decoder for generating a sense word line designation signal and a restore row decoder for generating a restore word line designation signal may be provided separately. In the case of this configuration, word drive circuits provided to sense word line SWL and to restore word line RWL, respectively, can be arranged on both sides oppositely to each other. Therefore, even in a case where a pitch between word lines becomes smaller, word line drive circuits can be arranged at the word line pitch by arranging sense and restore word line drive circuits on both sides of word lines SWL and RWL oppositely to each other.

Note that sense word line SWL is used for transferring storage data in a selected memory cell, but is not used in a restore operation. Therefore, as far as a capacitive coupling noise between sense word line and sense bit lines or restore bit lines does not affect a sense operation or a restore operation, sense word line SWL can be deactivated at any timing after activation of a sense amplifier.

According to the first embodiment of the present invention, as described above, a memory cell is formed of one memory capacitor, a sense access transistor and a restore access transistor, and furthermore, sense word lines and sense bit lines are provided separately from restore word lines and restore bit lines. A sense operation and a restore operation can be performed individually. Therefore, during restoration, a sense operation is completed and selection of a memory cell in the next cycle can be performed, and furthermore, during sense operation, access to memory cell data can be made. By performing sense and restore operations in an interleaved fashion, high speed access can be achieved.

Since a sense amplifier is coupled to sense bit lines through high input impedance and sense output signal lines and sense bit lines are electrically isolated. Thus, a potential amplitude on a sense bit line can be smaller, and time required for equalization on the sense bit lines can be reduced and in addition, power consumption can be reduced.

[Second Embodiment]

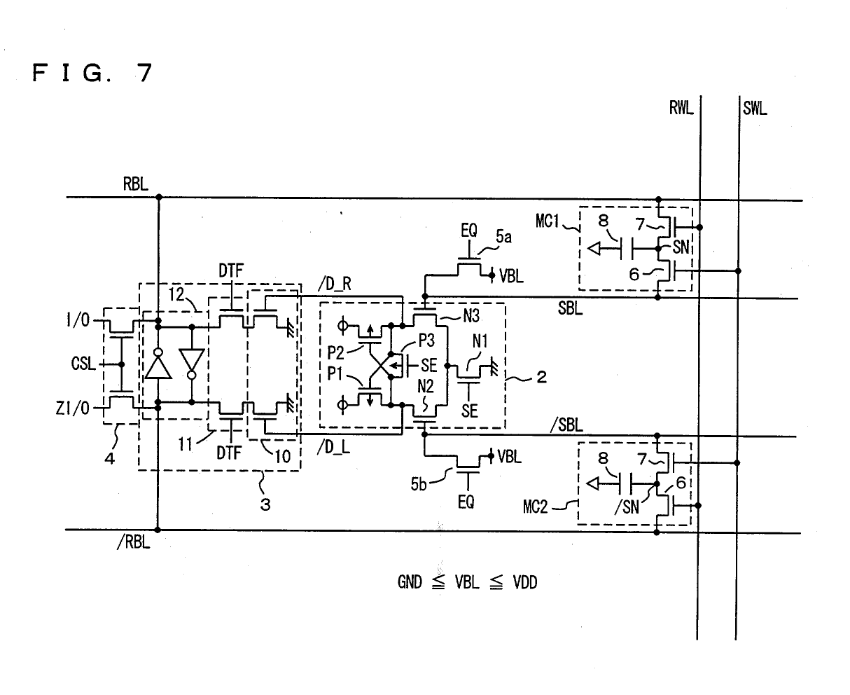

FIG. 7 is a diagram showing a configuration of a main part of a semiconductor memory device according to a second embodiment of the present invention. In the second embodiment as well, memory cells MC are arranged in rows and columns. In FIG. 7, there are representatively shown memory cells MC1 and MC2 arranged in one row and two columns. Sense word line SWL and restore word line RWL are provided corresponding to a memory cell row. In the second embodiment, for sense amplifier 2, sense bit lines SBL and /SBL are arranged, in a pair, extending in parallel to each other in the same direction. Furthermore, for restore amplifier 3, restore bit lines RBL and /RBL in a pair are arranged extending in parallel to each other in the same direction.

Similarly to the case of the first embodiment, memory cells MC1 and MC2 each include a sense access transistor 6, a restore access transistor 7 and a memory capacitor 8.

Sense bit lines SBL and /SBL are coupled to sense amplifier 2 and restore bit lines RBL and /RBL are driven by restore amplifier 3. Memory cells MC1 and MC2, sharing sense amplifier 2 and restore amplifier 3, store data complementary to each other. Specifically, when sense word line SWL is selected, sense access transistors 6 of memory cells MC1 ad MC2 both turn conductive to transmit data complementary to each other from storage node SN and /SN onto sense bit lines SBL and /SBL, respectively. Accordingly, one bit data is stored by two memory cells.

Sense amplifier 2 is of the same configuration as in the first embodiment, and the gates of MOS transistors N2 and N3 at an input stage (differential stage) are coupled to sense bit lines SBL and /SBL, and receives data read out from memory cells MC1 and MC2 with a high input impedance for amplification. The configuration of sense amplifier 2 is the same as that in the first embodiment, the same reference symbols are attached to corresponding components and detailed descriptions thereof will not be repeated.

Restore amplifier 3, similarly in the first embodiment, includes: a differential stage 10 amplifying complementary output signals from sense amplifier 2; a transfer gate 11 transferring output signals from differential stage 10 in response to transfer instruction signal DTF; and a latch circuit 12 latching data transferred from transfer gate 11. Complementary data is generated by latch circuit 12, transferred to restore bit lines RBL and /RBL and further transferred to storage nodes SN and /SN of respective memory cells MC1 and MC2 through corresponding restore accesses transistors 7.

Such a configuration is called the “folded bit line configuration” that sense bit lines SBL and /SBL are provided in pair on the same side relative to sense amplifier 2 and restore bit lines RBL and/RBL are provided in pair on the same side relative to restore amplifier 3. There are provided equalize transistors 5a and 5b for equalizing respective sense bit lines SBL and /SBL to prescribed voltage VBL.

Latch nodes of restore amplifier 3, or restore bit lines RBL and /RBL are coupled to column select gate 4. Column gate 4 is rendered conductive by column select signal SCL, when selected, to couple internal data lines I/O and ZI/O to respective restore bit lines RBL and /RBL.

In the folded bit line structure shown in FIG. 7 as well, a series of operations including a sense operation, a transfer operation of sense data to restore amplifier 3 and a restore operation of transferring data from restore amplifier 3 to memory cells are performed similarly to the first embodiment. Therefore, in the second embodiment as well, a cycle time can be greatly reduced.

Complementary data are held in memory cells MC1 and MC2, and one bit data is stored by two memory cells. Such configuration is equivalent to the configuration of storing one bit data by two memory capacitors 8, and a refresh time can be greatly longer. That is, in a case where a capacitance of a memory capacitor is doubled, a bit line read voltage increases by a factor of about 1.5, and a voltage drop rate at storage nodes of memory capacitors decreases by a factor of about 2, and therefore, a refresh cycle can be increased to be approximately tripled.

Especially, in a case where complementary data is stored in storage nodes SN and /SN, as shown in FIG. 7, a positive read voltage is transmitted onto one sense bit line, while a negative read voltage is transmitted onto the other sense bit line. The absolute values of read voltages of H level data and L level data are the same as each other. Therefore, since a voltage difference between sense bit lines SBL and /SBL becomes twice as large as that in a case where data from a memory cell is read out onto one sense bit line with the other sense bit line maintained at equalize voltage VBL and used as a reference bit line, and therefore, a high speed sense operation can be achieved. In this case, if a sense margins is the same, an activation timing of sense amplifier 2 can be more advanced.

In a case where the substrate of memory cells MC1 and MC2 is biased to a negative voltage, a potential level at storage node SN or ISN storing L level data falls down to a negative voltage from ground voltage through a junction leakage current. Therefore, even if electric charges in storage nodes storing H level data and L level data are lost through a junction leakage or the like, a voltage difference between complementary. data can be maintained. A refresh cycle can be lengthened up to a period at which the potential difference finally falls down below a sense margin of sense amplifier 2, to further reduce the number of times of refresh significantly.

It is not particularly required to use an intermediate voltage half as high as power supply voltage VDD as equalize voltage VBL. Specifically, even if equalize voltage VBL is power supply voltage VDD or ground voltage GND, or even if equalize voltage VBL is any voltage of between power supply voltage and ground voltage, data reverse in logic level from each other are read onto sense bit lines SBL and /SBL from respective memory cells MC1 and MC2. Therefore, since a potential difference is always generated between sense bit lines SBL and /SBL regardless of a voltage level of equalize voltage VBL, a sense operation can be certainly performed by sense amplifier 2. Therefore, a bias voltage level optimal to operation of sense amplifier 2 can be used for equalize voltage VBL to the sense bit lines and by setting equalize voltage VBL to a level in a so-called hit region of the sense amplifier, a high speed sense operation can be achieved.

In a write or restore operation, complementary data are transmitted onto restore bit lines RBL and /RBL. Data at power supply voltage and ground voltage levels are transmitted onto respective restore bit lines in a pair. In a case where there arises a defect such as a small drive ability or a high parasitic resistance in one of restore transistors 7 of respective memory cells MC1 and MC2, only insufficient restoration is performed on a memory cell with the defective restore access transistor. In this case as well, however, sufficient restoration can be performed at a storage node of a memory capacitor of the other memory cell. Therefore, it is not required to determine a restore time in consideration of a characteristic of a defective restore access transistor, thereby achieving high speed restore operation. Furthermore, with the configuration of storing one bit data by the use of two memory cells, even if a restore access transistor in one of memory cell in a pair is a defective access transistor, the restore operation can be performed with the defective access transistor used equivalently as a normal access transistor, to repair the defective memory cell. resulting in increased product yield.

According to the second embodiment of the present invention, as described above, bit lines are arranged in the folded bit line configuration, and one bit data is stored with two memory cells and complementary data are transmitted on bit lines in pair. Thus, sense and restore times can be reduced, and further high speed access can be achieved. Furthermore, a refresh interval can be longer, thereby enabling decrease in power consumption.

Third Embodiment

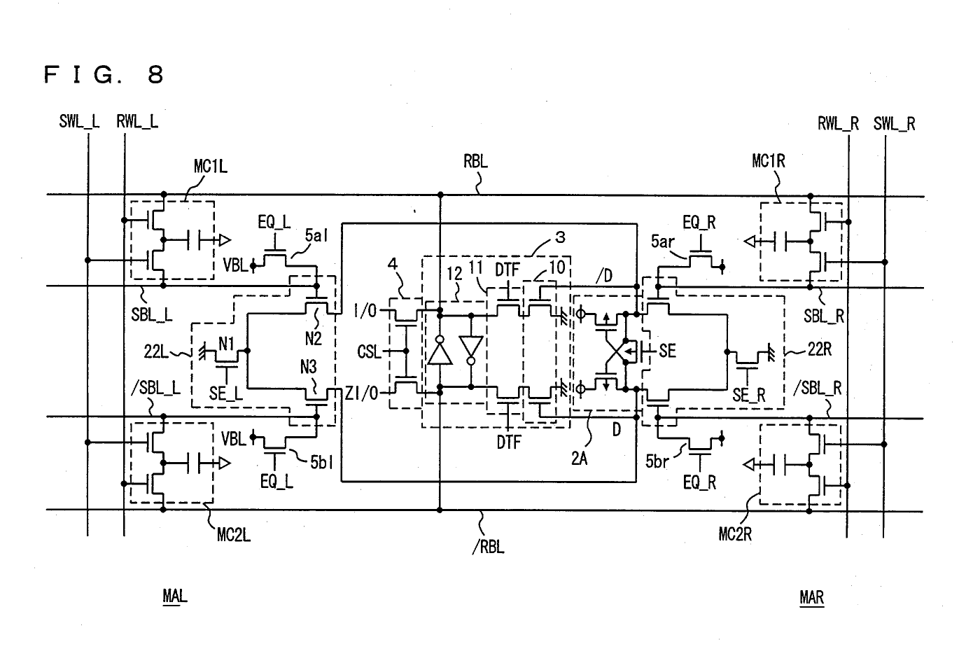

FIG. 8 is a diagram showing a configuration of a main part of a semiconductor memory device according to a third embodiment of the present invention. In FIG. 8, sense bit lines SBL and restore bit lines RBL are arranged in the folded bit line configuration. In the configuration shown in FIG. 8, a memory cell array is divided into two memory arrays MAR and MAL. Restore bit lines RBL and /RBL are arranged continuously extending over and commonly to memory cell arrays MAR and MAL. Therefore, restore amplifier 3 is shared between memory cells in memory arrays MAR and MAL.

On the other hand, as for a sense amplifier, a sense differential stage 22R is coupled to sense bit lines SBL_R and /SBL_R in memory array MAR and a sense differential stage 22L is coupled to sense bit lines SBL_L and SBL_R in memory array MAL. Sense differential stages 22R and 22L each include MOS transistors having gates connected to corresponding sense bit lines. Sense differential stage 22R is activated by sense activation signal SE_R and sense differential stage 22L is activated by sense activation signal SE_L. Sense differential stages 22R and 22L are coupled commonly to a sense load circuit 2A. Sense load circuit 2A includes cross-coupled P-channel MOS transistors and precharges sense output signal lines /D and D to power supply voltage VDD level when sense amplifier activation signal SE is deactivated.

In memory array MAR, memory cells MC1R and MC2R are arranged on the same row and in memory array MAL, memory cells MC1L and MC2L are arranged on the same row. One bit data is stored with memory cells MC1R and MC2R and one bit data is stored with memory cells MC1L and MC2L.

Equalize transistors 5ar and 5br rendered conductive in response to equalize instruction signal EQ_R are connected to respective sense bit lines SBL_R and /SBL_R. Equalize transistors 5al and 5bl rendered conductive in response to equalize instruction signal EQ_L are connected to respective sense bit lines SBL_L and /SBL_L.

In the configuration shown in FIG. 8, when a memory cell is selected, for example, in memory array MAR, sense word line SWL_R is at first driven into selected state to read out mutually complementary storage data in memory cells MC1R and MC2R onto sense bit lines SBL_R and /SBL_R. Memory array MAR in the left side maintains the non-selected state and sense bit lines SBL_L and /SBL_L are equalized to equalize voltage VBL.

Then, sense amplifier activation signal SE_R is activated to activate sense differential stage 22R, to differentially amplify a potential difference between sense bit lines SBL_R and /SBL_R for lowering one of potentials on sense output lines D and /D. On the other hand, sense amplifier activation signal SE is activated simultaneously with activation of sense amplifier activation signal SE_R to activate sense load circuit 2A to maintain potentials on sense output signal lines D and /D at high level. Sense differential stage 22L at this time is in inactive state and in sense differential stage 22L, MOS transistor N1 is in non-conductive state. Therefore, a magnified potential difference of a potential difference generated between sense bit lines SBL_R and /SBL_R can be generated onto sense output lines D and /D with the help of sense load circuit 2A even if MOS transistors N2 and N3 are conductive by equalize voltage VBL in the sense differential stage 22L. When equalize voltage VBL is, for example, an intermediate level, the equalize voltage on sense output lines D and /D is power supply voltage level and differential MOS transistors N2 and N3 in sense differential stage 22L can function as decouple transistors, thereby enabling a correct sense operation.

When transfer instruction signal DTF is activated after completion of a sense operation at a prescribed timing or after the start of a sense operation, a potential difference between sense output signal lines D and /D are transferred to latch circuit 12 and restore bit lines RBL and /RBL are driven to power supply voltage and ground voltage levels.

Restore word line RWL_R is driven into selected state in response to activation of transfer instruction signal DTE to turn restore access transistors of memory cells MC1R and MC2R conductive, to thereby perform restoration of memory cell data.

In the configuration shown in FIG. 8, memory arrays MAR and MAL share restore amplifier 3 and sense load circuit 2A. Therefore, a layout area of sense and restore amplifiers can be reduced as a whole.

First Modification

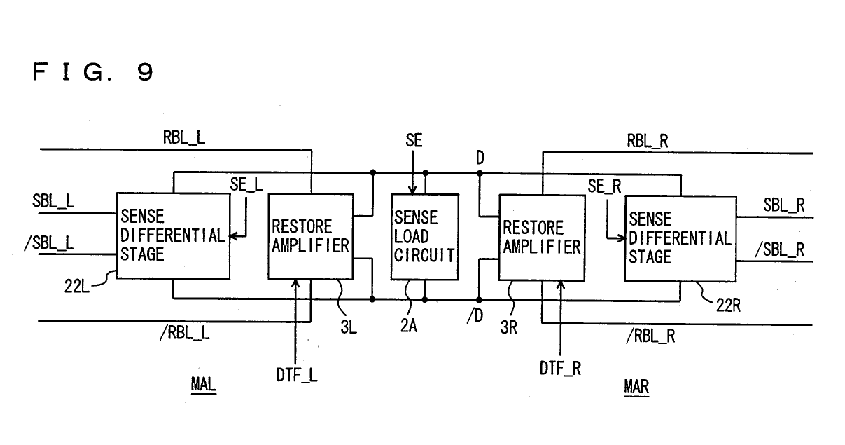

FIG. 9 is a diagram schematically showing a configuration of a first modification of the third embodiment of the present invention. In FIG. 9, in memory array MAR, sense bit lines SBL_R and /SBL_R are coupled to sense differential stage 22R and restore bit lines RBL_R and /RBL_R are connected to restore amplifier 3R.

In memory array MAL, sense bit lines SBL_L and /SBL_L are coupled to sense differential stage 22L and restore bit lines RBL_L and /RBL_L are connected to restore amplifier 3L.

Sense differential stages 22R and 22L are activated by respective sense amplifier activation signals SE_R and SE_L. Sense differential stages 22R and 22L are coupled commonly to sense load circuit 2A. Sense load circuit 2A drives sense output lines /D and D in response to activation of sense amplifier activation signal SE. Sense amplifier activation signal SE_R and SE_L are each activated according to block select signal and sense amplifier activation signal SE.

Restore amplifiers 3R and 3L takes in and latches signals on sense output lines D and /D in response to respective transfer instruction signals DTF_R and DTF_L.

In the configuration shown in FIG. 9, sense differential stages and restore amplifiers are provided correspondingly to respective memory arrays MAR and MAL and sense load circuit 2A is shared by memory arrays MAR and MAL. Therefore, in this configuration as well, a layout area for sense amplifiers can be reduced as a whole, compared with a configuration in which restore amplifiers and sense amplifiers are provided to respective memory arrays MAR and MAL separately.

Restore amplifier 3R merely drives restore bit lines RBL_R and /RBL_R of memory array MAR and restore amplifier 3L also merely drives restore bit lines RBL_L and /RBL_L of memory array MAL. Therefore, a load on a restore amplifier is reduced, compared with a configuration in which one restore amplifier is shared by memory arrays MAR and MAL, thereby achieving a high speed restore operation.

Second Modification

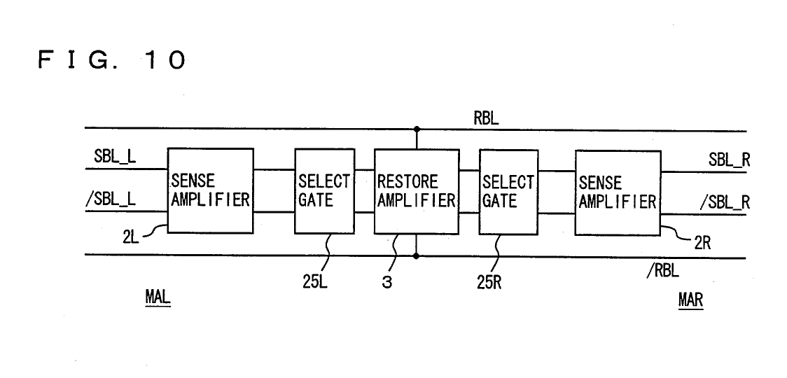

FIG. 10 is a diagram schematically showing a configuration of a second modification of the third embodiment of the present invention.

In FIG. 10, sense amplifier 2R is coupled to sense bit lines SBL_R and /SBL_R of memory array MAR and sense amplifier 2L is coupled to sense bit lines SBL_L and /SBL_L of memory array MAL. Sense amplifier 2R is coupled to restore amplifier 3 through select gate 25R and sense amplifier 2L is coupled to restore amplifier 3 through select gate 25L. Sense amplifiers 2L and 2R each include a sense differential stage and a sense load circuit.

Restore amplifier 3 are connected to restore bit lines RBL and /RBL arranged extending in a column direction commonly to memory arrays MAR and MAL. Specifically, sense amplifiers 2R and 2L are provided to respective memory arrays MAR and MAL, while restore amplifier 3 is shared between memory arrays MAR and MAL.

FIG. 11 is a diagram showing an example of specific configuration of select gates 25L and 25R and restore amplifier 3 shown in FIG. 10. In the configuration shown in FIG. 11, restore amplifier 3 and select gates 25L and 25R are integrated into restore amplifier 3.

In FIG. 11, restore amplifier 3 includes: N-channel MOS transistors N10 and N12 having gates connected to sense output lines /D_L and D_L of sense amplifier 2L; an N-channel MOS transistor N11 connected in series between restore bit lines RBL and MOS transistor N10 and receiving transfer instruction signal DTF_L at a gate thereof, and N-channel MOS transistor N13 connected in series between restore bit line /RBL and MOS transistor N12 and receiving transfer instruction signal DTF_L at a gate thereof; N-channel MOS transistors N20 and N22 having gate connected to respective sense output lines /D_R and D_R of sense amplifier 2R; and N-channel MOS transistors N21 and N23 connected in series between restore bit lines /RBL, RBL and MOS transistor N20, N22, respectively. Transfer instruction signal DTF_R is applied to the gates of MOS transistors N21 and N23.

Transfer instruction signals DTF_R and DTF_L are generated in combinations of respective block select signals designating memory arrays MAR and MAL and transfer instruction signal DTF.

Therefore, for example, when memory array MAR is selected, transfer instruction signal DTF_R is activated to cause MOS transistors N21 and N22 to be conductive and latch circuit 12 latches data appearing on sense output lines /D_R and D_R to drive restore bit lines RBL and /RBL. in this case, transfer instruction signal DTF_L is in inactive state and MOS transistors N11 and N13 maintain non-conductive state.

Latch circuit 12 of restore amplifier 3 can be shared by memory arrays MAR and MAL, thereby enabling reduction in layout of restore amplifiers as a whole.

According to the third embodiment of the present invention, as described above, memory arrays provided on both sides of sense amplifiers and/or restore amplifiers share at least a part of the sense amplifiers and the restore amplifiers, thereby enabling reduction in array layout area.

Fourth Embodiment

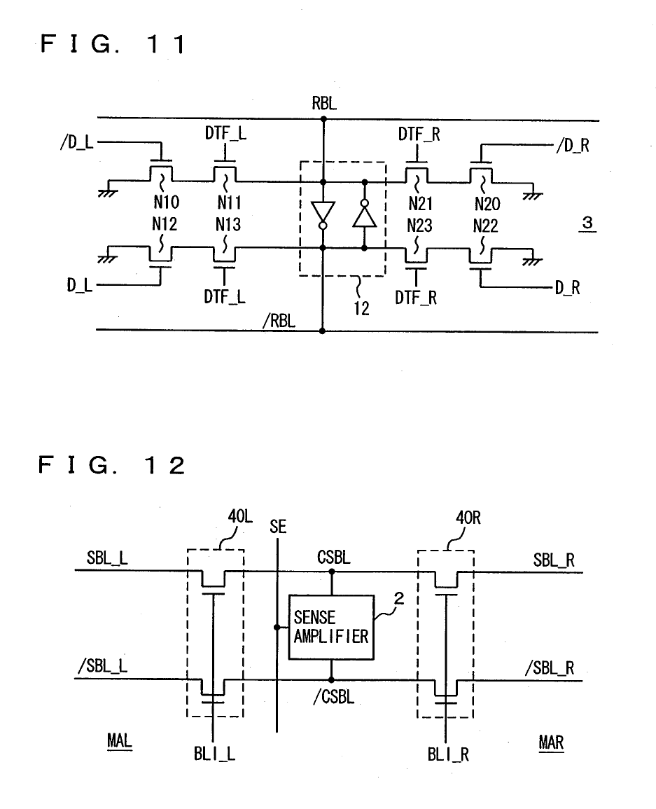

FIG. 12 is a diagram schematically showing a configuration of a main part of a semiconductor memory device according to a fourth embodiment of the present invention. In FIG. 12, bit lines are arranged in the folded bit line configuration. Sense bit lines SBL_R and /SBL_R of memory array MAR in the right side are coupled to common sense bit lines CSBL and /CSBL through a bit line isolation gate 40R. Sense bit lines SBL_L and /SBL_L of memory array MAL in the left side are coupled to common sense bit lines CSBL and /CSBL through a bit line isolation gate 40L. Sense amplifier 2 is coupled to common sense bit lines CSBL and /CSBL. Sense amplifier 2 performs a sense operation in response to activation of sense amplifier activation signal SE.

Bit line isolation gate 40R is rendered conductive, when a bit line isolation instruction signal BLI_R is at H level, to couple sense bit lines SBL_R and /SBL_R to respective common sense bit lines CSBL and /CSBL.

On the other hand, bit line isolation gate 40L is rendered conductive, when a bit line isolation instruction signal BLI_L is at H level, to couple sense bit lines SBL_L and /SBL_L to respective common sense bit lines CSBL and /CSBL.

Bit line isolation instruction signal BLI_R is driven to L level when memory array MAL is selected, while bit line isolation instruction signal BLI_L is driven to L level when memory array MAR is selected.

Therefore, in a sense operation, only sense bit lines of a selected memory array are connected to sense amplifier 2, thereby enabling reduction in an input capacitance of sense amplifier 2. Therefore, a capacitance ratio of a sense input node to a memory capacitor can be large to produce a large change in voltage at the input nodes of sense amplifier 2 according to memory cell data, and a sense operation can be performed correctly. Under the same sense margin, sense start timing can be made earlier.

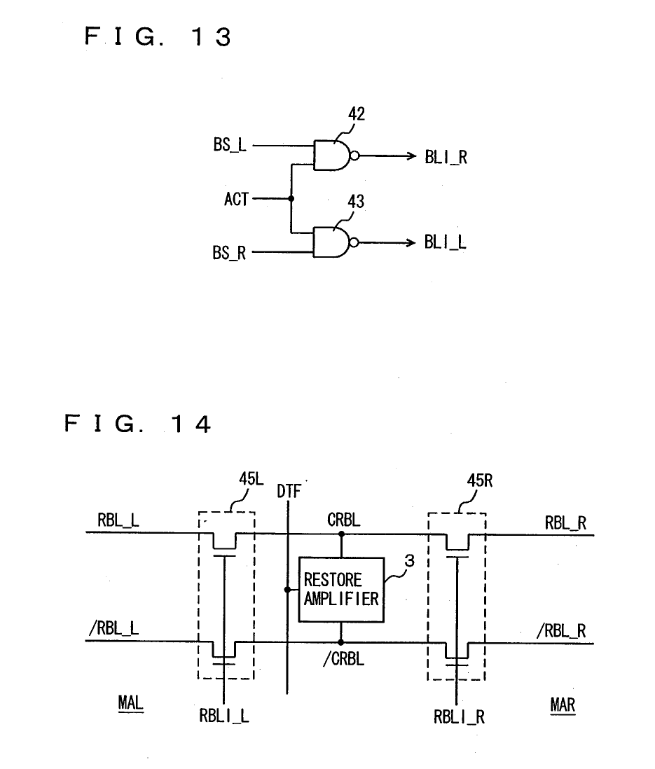

FIG. 13 is a diagram showing an example of a configuration of a part generating a bit line isolation instruction signal shown in FIG. 12. In FIG. 13, a bit line isolation instruction generating section includes: a NAND circuit 42 receiving block select signal BS_L designating memory array MAL and row access instruction signal ACT to generate bit line isolation instructing signal BLI_R; and a NAND circuit 43 receiving block select signal BS_R designating memory array MAR and row access instruction signal ACT to generate bit line isolation instructing signal BLI_L.

When row access instruction signal ACT is in inactive state, bit line isolation instructing signals BLI_R and BLI_L are both at H level. When block select signal BS_L attains H level, bit line isolation instructing signal BLI_R is set to L level during a period in which row access instruction signal ACT is at H level, to isolate sense bit lines SBL_R and /SBL_R from sense amplifier 2. On the other hand, when block select signal BS_R is selected, bit line isolation instructing signal BLI_L is set to L level during a period in which row access instruction signal ACT is in active state, to isolate sense bit lines SBL_L and /SBL_L from sense amplifier 2.

In a case where equalize voltage VBL on sense bit lines SBL and /SBL is at an intermediate voltage level, memory cell data can be sufficiently transmitted to sense amplifier 2 even when bit line isolation instructing signals BLI_R and BLI_L are at power supply voltage level since a potential amplitude on sense bit lines SBL and /SBL is small. In a case where bit line equalize voltage VBL is at power supply voltage level or where memory cell data is transmitted to sense amplifier 2 at high speed, a level shift function is provided to NAND circuits 42 and 43 shown in FIG. 13 to set H level of bit line isolation instructing signals BLI_R and BLI_L to a boosted voltage level higher than power supply voltage.

Note that for restore amplifier 3, any of the configurations described with reference to FIGS. 9 to 11 in the fourth embodiment may be employed.

According to the fifth embodiment of the present invention, as described above, sense bit lines are coupled to a sense amplifier through a bit line isolation gate and sense amplifier 2 receiving signals at the gates of MOS transistors therein can be shared between memory arrays MAR and MAL, thereby enabling reduction in a layout area of sense amplifiers.

A load on sense input nodes of a sense amplifier can be reduced and memory cell data can be transferred to the sense input nodes at high speed to perform a sense operation.

Fifth Embodiment

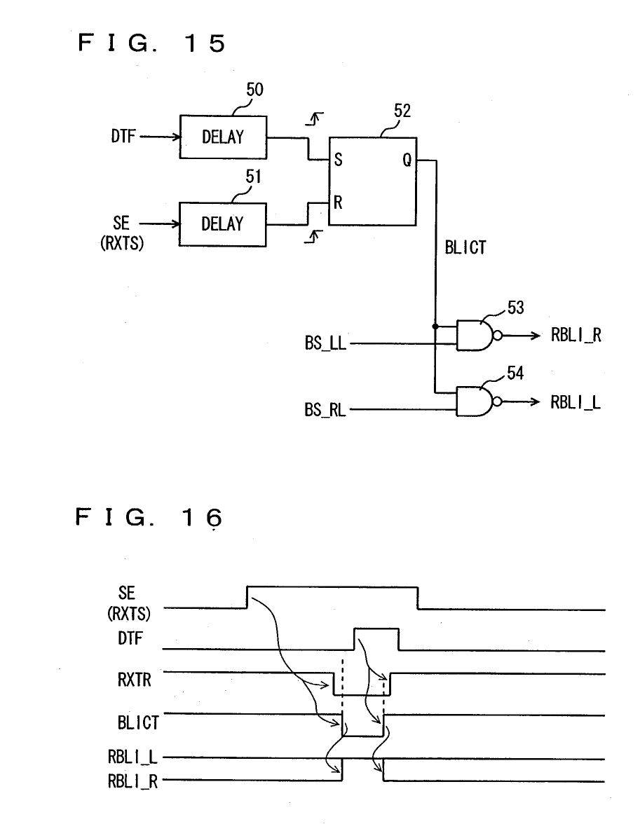

FIG. 14 is a diagram schematically showing a main part of a semiconductor memory device according to a fifth embodiment of the present invention. In FIG. 14, restore bit lines RBL_R and /RBL_R of memory array MAR are coupled to respective common restore bit lines CRBL and /CRBL through a restore bit line isolation gate 45R. Restore bit lines RBL_L and /RBL_L of memory array MAL are coupled to respective common restore bit lines CRBL and /CRBL through a restore bit line isolation gate 45L. Restore amplifier 3 takes in and latches data from a sense amplifier not shown according to transfer instruction signal DTF to drive restore bit lines of a selected memory array according to the latching data.

Restore amplifier 3 is required only for driving restore bit lines of a selected memory array, thereby enabling reduction in driving load thereof and a high speed restore operation of a selected memory cell. Furthermore, since a load capacitance of restore bit lines to be driven is reduced to one half times, a consumed current can be decreased in restore operation.

Restore bit line isolation gate 45R turns selectively conductive according to restore bit line isolation instructing signal RBLI_R and restore bit line isolation gate 45L turns selectively conductive according to restore bit line isolation instructing signal RBLI_L. Since restore amplifier 3 transmits signals at power supply and ground voltage levels, H level of restore bit line isolation instructing signals RBLI_L and RBLI_R is preferably set to a boosted voltage level higher than power supply voltage. In a case where a voltage of an activated restore word line is at power supply voltage level and a voltage level of H level data stored in a memory cell is lower than power supply voltage by a threshold voltage of a restore access transistor, there is no particular necessity of setting H level of restore bit line isolation instructing signals RBLI_L and RBLI_R at the boosted voltage level.

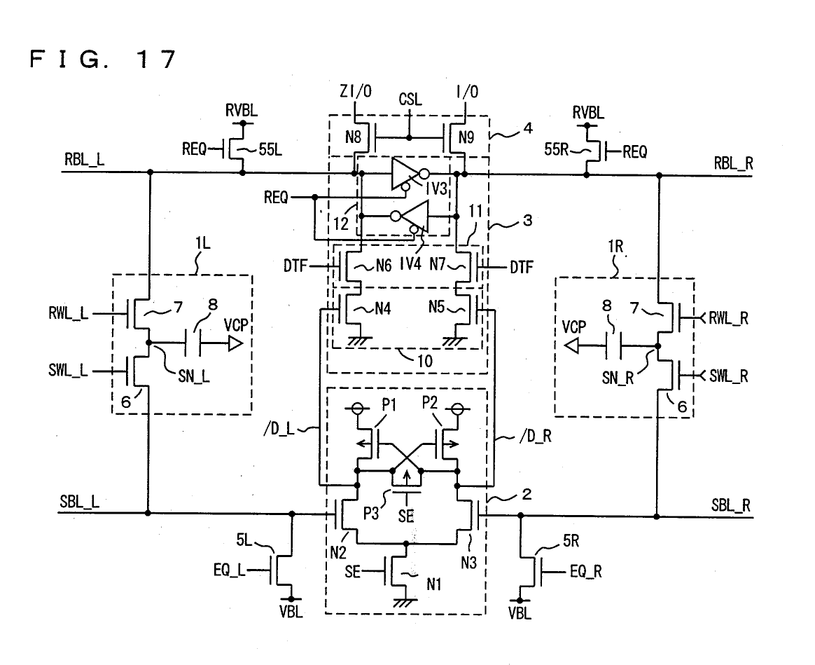

FIG. 15 is a diagram showing an example of a configuration of a part generating a restore bit line isolation instructing signal shown in FIG. 14. In FIG. 15, a restore bit line isolation instructing signal generating section includes: a delay circuit 50 for delaying transfer instruction signal DTF by a prescribed time; a delay circuit 51 for delaying sense amplifier activation signal SE by a prescribed time; a set/reset flip-flop 52 set in response to a rise of an output signal of delay circuit 50, and reset in response to a rise of an output signal of delay circuit 51, to generate a common isolation control signal BLICT; a NAND circuit 53 receiving latch block select signal BS_LL and common isolation control signal BLICT to generate restore bit line isolation instructing signal RBLI_R; and a NAND circuit 54 receiving restore bit line isolation control signal BLICT and latch block select signal BS_RL to generate restore bit line isolation instructing signal RBLI_L.

Latch block select signals BS_LL and BS_RL are generated from latch circuits taking block select signals BS_L and BS_R outputted from a block decoder decoding a block address designating a memory array according to transfer instruction signal DTF (see FIG. 3).

In the configuration shown in FIG. 15, when a prescribed period elapses after activation of sense amplifier activation signal SE, common isolation control signal BLICT is reset to L level and restore bit line isolation instructing signals RBLI_L and RBLI_R both attain H level. H level of the signals outputted by NAND circuits 53 and 54 may be power supply voltage level or may be the boosted voltage level.

When restore bit line isolation control signal BLICT is activated, restore bit lines disconnected by latch block select signal BS_LL and BS_RL latched in the previous cycle are connected to the restore amplifier. As shown in FIG. 16, a restore word line drive timing signal RXTR enters inactive state in response to sense amplifier activation signal SE and a sense word line drive signal prior to activation of transfer instruction signal DTF, and a restore word line selected in the previous cycle is driven into non-selected state. In this state, restore bit line isolation instructing signals RBLI_R and RBLI_L both attain H level to turn restore bit line isolation gates 45R and 45L conductive.

Subsequently, when transfer instruction signal DTF is activated, set/reset flip-flop 52 is set according to an output signal of delay circuit 50 and common isolation control signal BLICT is again activated to drive one of restore bit line isolation instructing signals RBLI_L and RBLI_R to H level and the other to L level according to latch block select signals BS_LL and BS_RL. Thereafter, restore word line drive timing signal RXTR is activated, a restore operation is performed on a memory cell connected to a selected restore word line.

According to the fifth embodiment of the present invention, as described above, in the configuration where restore amplifier 3 is shared by memory arrays MAR and MAL, restore bit line isolation gates are used to reduce a load driven by restore amplifier 3, thereby enabling a high speed restore operation.

Furthermore, a load capacitance of restore bit lines to be driven is reduced, thereby enabling reduction in consumed current in restore operation.

Moreover, since a restore amplifier is shared by memory arrays, a layout area for restore amplifiers can be decreased compared with a configuration in which restore amplifiers are provided to respective memory arrays.

Note that the sharing configurations utilizing isolation gates to a sense amplifier and to a restore amplifier as shown in FIGS. 12 and 14, may be employed in combination.

Sixth Embodiment

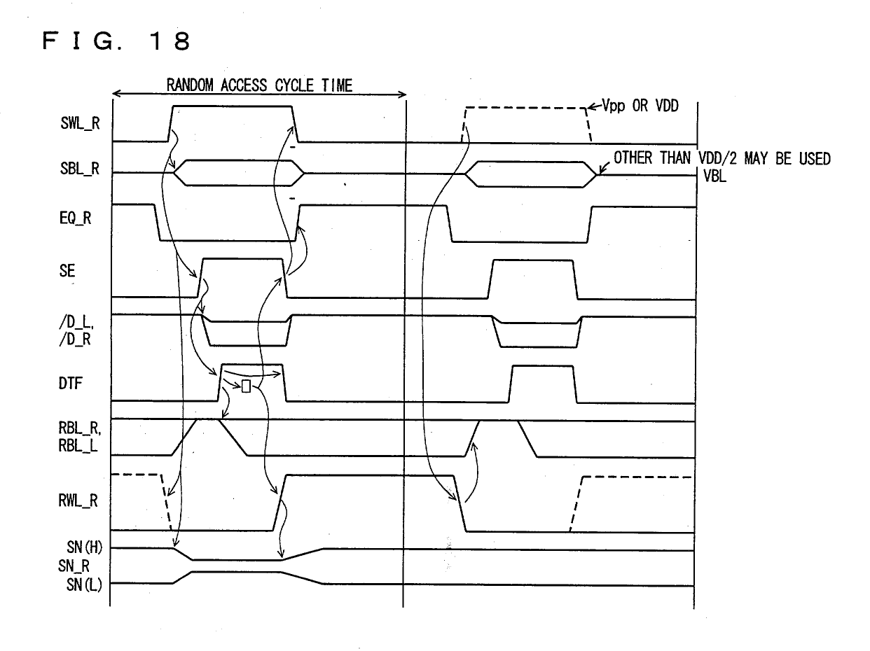

FIG. 17 is a diagram schematically showing a main part of a semiconductor memory device according to a sixth embodiment of the present invention. The configuration in FIG. 17 is different from the configuration shown in FIG. 1 in the following respects. That is, an equalize transistor 55R rendered conductive in response to restore bit line equalize instruction signal REQ is provided to restore bit line RBL_R and an equalize transistor 55L rendered conductive in response to restore bit line equalize instruction signal REQ is provided to restore bit line RBL_L. Equalize transistors 55R and 55L, in conductive state, transmit a restore bit line equalize voltage RVBL to corresponding restore bit lines RBL_R and RBL_L.

In restore amplifier 3, latch circuit 12 is formed of tristate inverter buffers IV3 and IV4 entering an output high impedance state in response to activation of restore bit line equalize instruction signal REQ. The other part of the configuration shown in FIG. 17 is the same as the configuration shown in FIG. 1, the same reference symbols are attached to corresponding components and detailed descriptions thereof will not be repeated.

In the configuration shown in FIG. 17, restore bit line RBL_R and RBL_L are once equalized to equalize voltage RVBL prior to restore operation. Thus, starting voltages on restore bit line RBL_R and RBL_L when restore voltages are transmitted, are at the same voltage level, so that timings at which voltages on restore bit lines RBL_R and RBL_L are made definite can be constant regardless of transmitted data at all times.

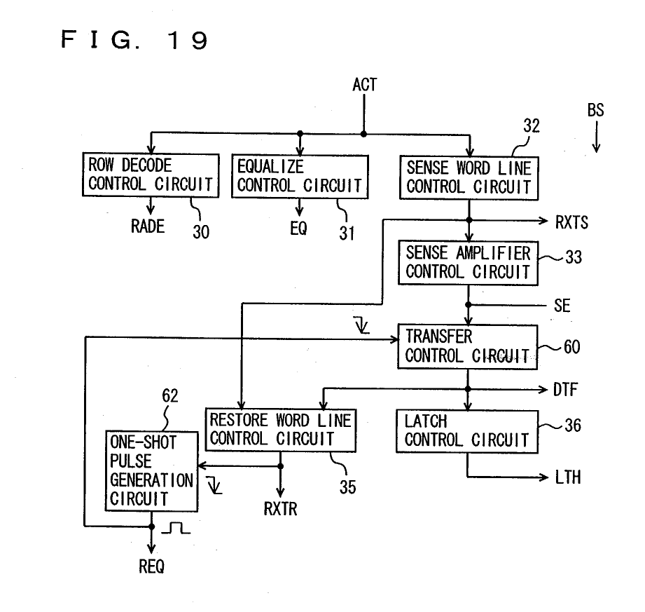

FIG. 18 is a timing diagram representing operations of the configuration shown in FIG. 17. Description will be given of operations of the configuration shown in FIG. 17 below with reference to FIG. 18.

A case is considered where a sense word line SWL_R of a memory array in the right side is selected. First, when a sense cycle (random access cycle) defined by a row access instruction starts, equalize instruction signal EQ_R is deactivated to complete equalization of sense bit line SBL_R. Then, sense word line SWL_R is selected and storage data in memory cell 1R is transmitted onto sense bit line SBL_R. Subsequently, sense amplifier 2 is activated in response to activation of sense amplifier activation signal SE, to differentially amplify potentials on sense bit lines SBL_R and SBL_L to transmit resultant signals onto respective sense output lines /D_R and /D_L. Here, sense bit line SBL_L has been equalized to equalize voltage by equalize transistor 5L.

When sense word line SWL_R is activated (driven to selected state), restore word line RWL in selected state is driven into non-selected state after elapse of a prescribed time. Restore bit line equalize instruction signal REQ is activated in response to deactivation of restore word line RWL and kept active for a prescribed time to equalize restore bit lines RBL_R and RBL_L to equalize voltage RVBL. At this time, latch circuit 12 in restore amplifier 3 is in output high impedance state. When the equalize operation on restore bit lines RBL_R and /RBL_L is completed, transfer instruction signal DTF is activated. Data amplified by sense amplifier 2 is transferred to restore amplifier 3 to be latched therein, and the voltage levels on restore bit lines RBL_R and RBL_L are changed according to transfer data.

Then, when a prescribed time elapses after activation of transfer instruction signal DTF, restore word line RWL_R is driven into selected state to rewrite original data to sense node SN_R of memory cell 1R.

Therefore, if there is a margin in cycle time, change starting voltages on restore bit lines RBL_R and RBL_L can be set at the same voltage level at all times through equalization of restore bit lines. Thus, timings at which the signals on restore bit lines are made definite can be the same at all times even if current restore data is reverse data of restore data in the previous cycle.

Note that equalize voltage RVBL on restore bit lines are set to power supply voltage level in FIG. 18. Equalize voltages on restore bit lines, however, may be ground voltage level or may be a voltage between power supply voltage and ground voltage.

A timing at which completion of equalization of restore bit lines RBL_R and RBL_L and a timing of activation of data transfer instruction signal DTF may be the same as each other. In addition, data transfer instruction signal DTF may be activated after completion of equalization of restore bit lines.

FIG. 19 is a diagram schematically showing a configuration of a part generating control signals shown in FIG. 17. The configuration of a row related control signal generating section shown in FIG. 19 is different from the configuration of the row related control signal generating section shown in FIG. 5 in the following respects. That is, a restore word line control circuit 35 generating restore word line drive timing signal RXTR deactivates restore word line drive timing signal RXTR in response to and after elapse of a predetermined time period from activation of sense word line drive timing signal RXTS from sense word line control circuit 32, and then activate restore word line drive timing signal RXTR in response to and after elapse of a predetermined time period from activation of transfer instruction signal DTF from transfer control circuit 60.

Restore bit line equalize instruction signal REQ is generated from one-shot pulse generating circuit 62 generating a pulse signal in the form of one shot pulse in response to restore word line drive timing signal RXTR. One-shot pulse generating circuit 62 generates a one-shot pulse signal having a prescribed time width in response to deactivation of restore word line drive timing signal RXTR, to generate restore bit line equalize instruction signal REQ.

Transfer control circuit 60 generates a one-shot pulse signal having a prescribed time width when sense amplifier activation signal SE from sense amplifier control circuit 33 is in active state (at H level) in response to a fall of restore bit line equalize instruction signal REQ from one-shot pulse generating circuit 62, to generate transfer instruction signal DTF. Transfer control circuit 60 is formed of, for example, an AND gate receiving refresh bit line equalize instruction signal REQ and sense amplifier activation signal SE, and a one-shot pulse generating circuit generating a one-shot pulse signal having a prescribed time width in response to a fall of an output signal of the AND gate. After a sense operation by a sense amplifier is performed and an equalize operation on restore bit lines is completed, transfer instruction signal DTF is activated and the output signals of sense amplifier 2 are transferred to restore amplifier 3.

The other part of the configuration of the row-related control circuit shown in FIG. 19 is the same as the row-related control circuit shown in FIG. 5, the same reference symbols are attached to corresponding components of the configuration and detailed descriptions thereof will not be repeated.

According to the sixth embodiment of the present invention, as described above, restore bit lines are equalized to a prescribed voltage level for a prescribed period prior to data transfer to a restore amplifier from a sense amplifier and the starting voltage on restore bit lines when restore data is transferred is set at the same voltage level at all times. Thus, restore data can be transferred to a selected memory cell with certainty. Especially when equalize voltage RVBL on restore bit lines is at the intermediate voltage, a potential change on restore bit lines becomes smaller, thereby achieving high speed full swing of restore bit line voltages.

Seventh Embodiment

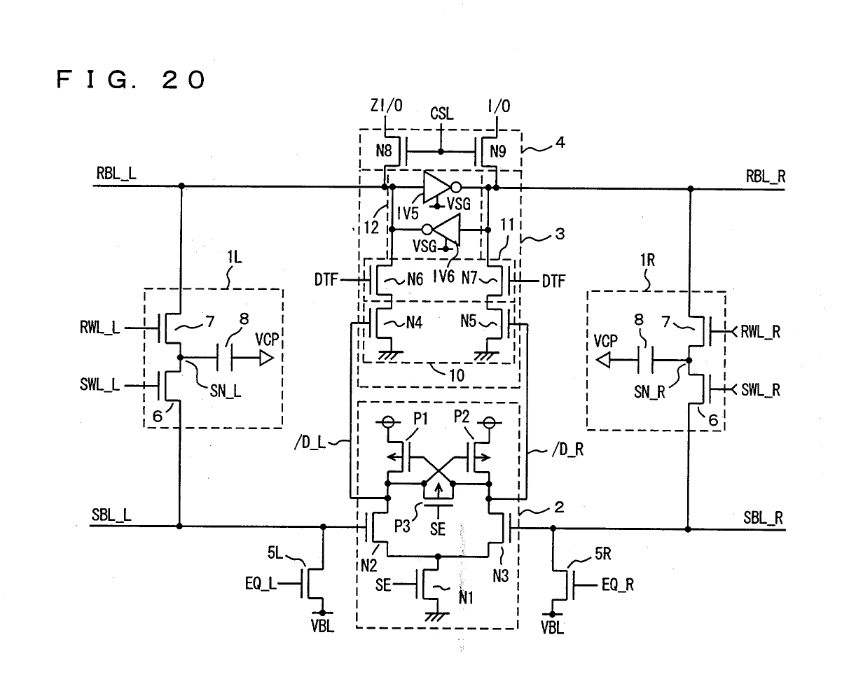

FIG. 20 is a diagram showing a main part of a semiconductor memory device according to a seventh embodiment of the present invention. The configuration shown in FIG. 20 is different from the configuration shown in FIG. 1 in the following respects: that is, latch circuit 12 of restore amplifier 3 is formed of inverters IV5 and IV6. A voltage VSG higher than ground voltage is applied as a low level power supply voltage to inverters IV5 and IV6. The other part of the configuration of FIG. 20 is the same in configuration as corresponding part of the configuration shown in FIG. 1, the same reference symbols are attached to corresponding components and descriptions thereof will not be repeated.

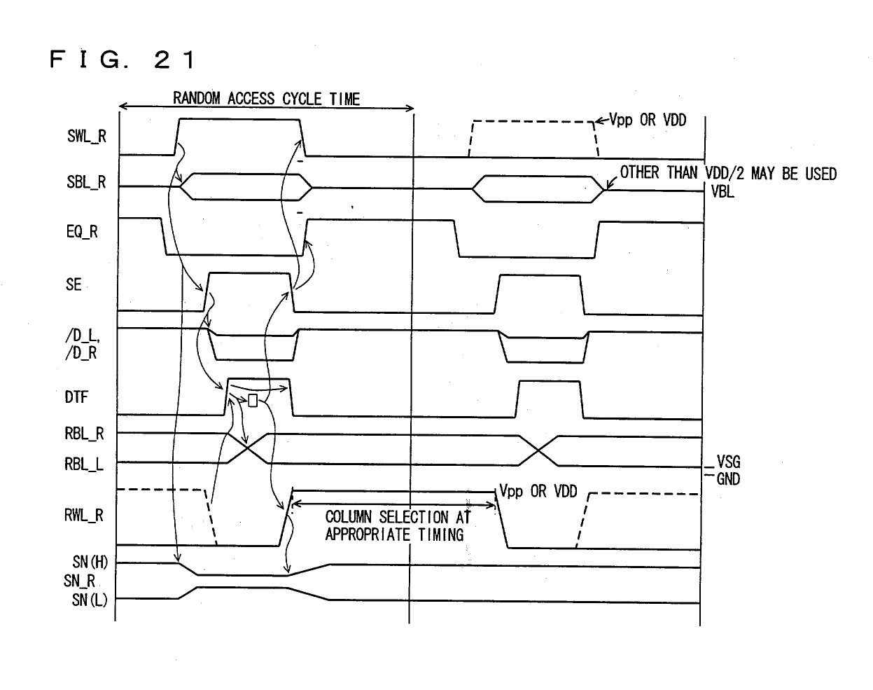

FIG. 21 is a timing diagram representing operations of the configuration shown in FIG. 20. In an operating waveform diagram shown in FIG. 21, in latch circuit 12 of restore amplifier 3, low level power supply voltage is at a voltage VSG level higher than ground voltage. Therefore, L level on restore bit lines RBL_R and RBL_L is set to voltage VSG higher than ground voltage GND. When restore bit lines is at ground voltage GND level while restore word line RWL_R is in non-selected state, a gate-to-source voltage of restore access transistor 7 becomes 0V. When H level data is stored in storage node SN_R, a subthreshold leakage current flows in restore access transistor 7 and electric charges flow out from storage node SN_R onto restore bit line RBL_R, causing a possibility of degradation of data holding characteristics.

By setting a voltage at L level on restore bit lines RBL_R and RBL_L to voltage VSG level higher than ground voltage GND level, a gate-to-source voltage of restore access transistor 7 becomes a negative voltage, setting the restore access transistor 7 to a reversely biased state even in non-selected state. Therefore, the restore access transistor can be set in deeper off state to suppress subthreshold leakage current and to prevent flowing-out of electric charges from storage node SN (SN_R and SN_L), improving the electric charge holding characteristics of a memory cell.

According to the seventh embodiment of the present invention, as described above, a L level voltage on restore bit lines is set to a voltage level higher than ground voltage, a gate-to-source voltage of restore access transistor in non-selected state can be set to in reversely biased state, thereby enabling suppression of subthreshold leakage current and achieving improved electric charge holding characteristics.

Eighth Embodiment

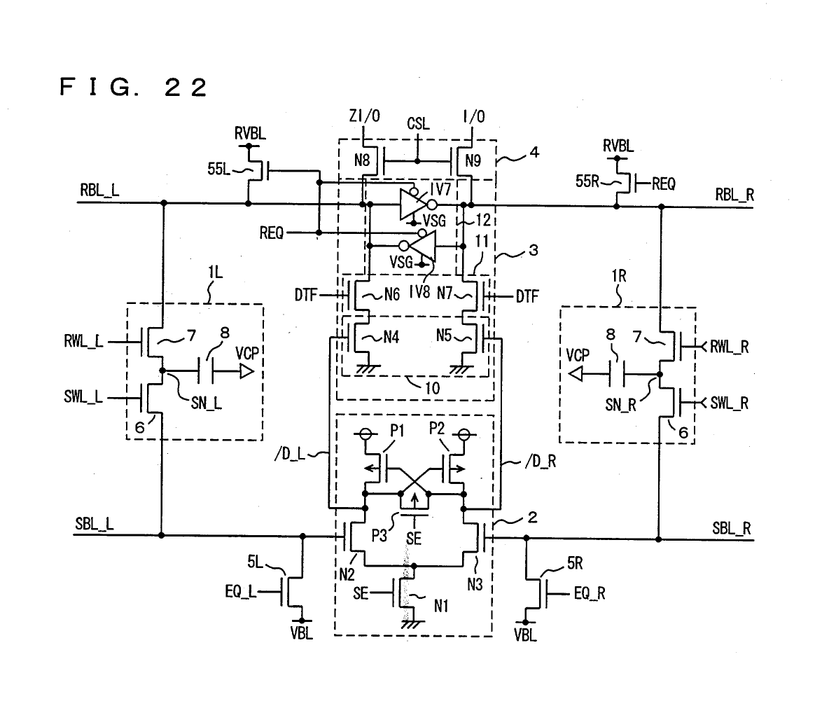

FIG. 22 is a diagram showing a main part of a semiconductor memory device according to an eighth embodiment of the present invention. The configuration shown in FIG. 22 is different from the configuration shown in FIG. 20 in the following respects: that is, a restore transistor 55R rendered conductive in response to restore bit line equalize instruction signal REQ is provided to restore bit line RBL_R and a restore transistor 55L rendered conductive in response to restore bit line equalize instruction signal REQ is provided to restore bit line RBL_L. Restore transistors 55R and 55L, in conductive state, transmit equalize voltage RVBL onto restore bit lines RBL_R and RBL_L.

In restore amplifier 3, inverters IV7 and IV8 constructing latch circuit 12 enter output high impedance state in activation of restore bit line equalize instruction signal REQ. Voltage VSG higher than ground voltage GND is applied to inverters IV7 and IV8 as low level power supply voltage, instead of ground voltage.

The other configuration shown in FIG. 22 is the same as the configuration shown in FIG. 20, the same symbols are attached to corresponding components and descriptions thereof will not be repeated.

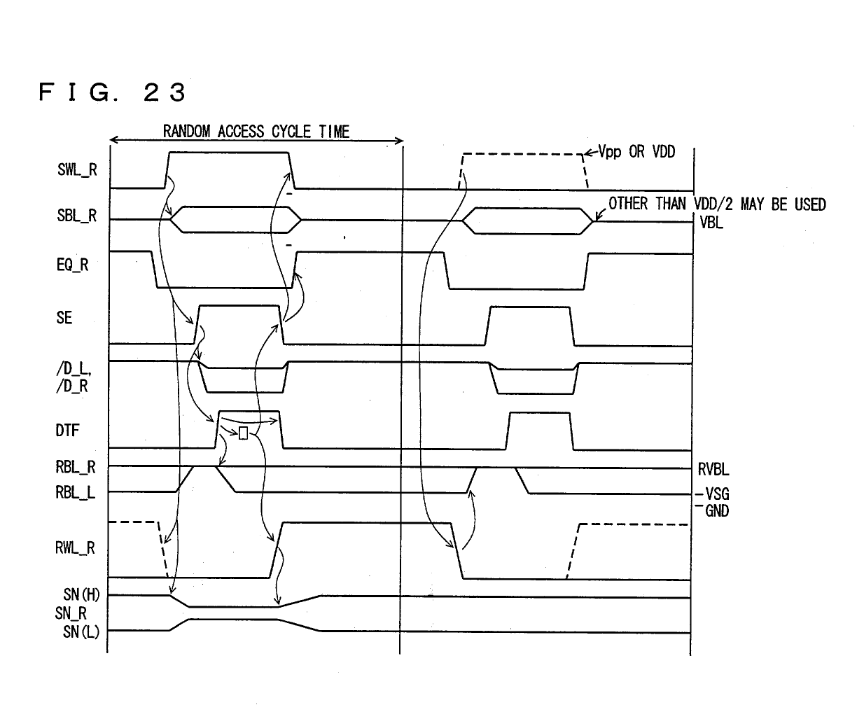

FIG. 23 is a signal waveform diagram representing operations of the configuration shown in FIG. 22. In FIG. 22, as shown in FIG. 23, restore bit lines RBL_R and RBL_L, after equalized to equalize voltage RVBL, are driven to H level and L level according to restore data. L level of restore bit lines RBL_R and RBL_L is voltage VSG level higher than ground voltage GND. In a configuration in which restore bit lines RBL_R and RBL_L are equalized to equalize voltage RVBL as well, data holding characteristics of a memory cell can be improved, similarly to the seventh embodiment, by setting L level potential on restore bit lines to a voltage level higher than ground voltage level.

In equalization of restore bit lines, an amplitude of a potential thereon can be reduced (in a case where equalize voltage RVBL is higher than voltage VSG), thereby achieving reduction in time required for equalization of restore bit lines.

Similarly to the sixth embodiment, by equalizing restore bit lines to a prescribed voltage level, high speed restoration can be achieved with a low consumed current.

Ninth Embodiment

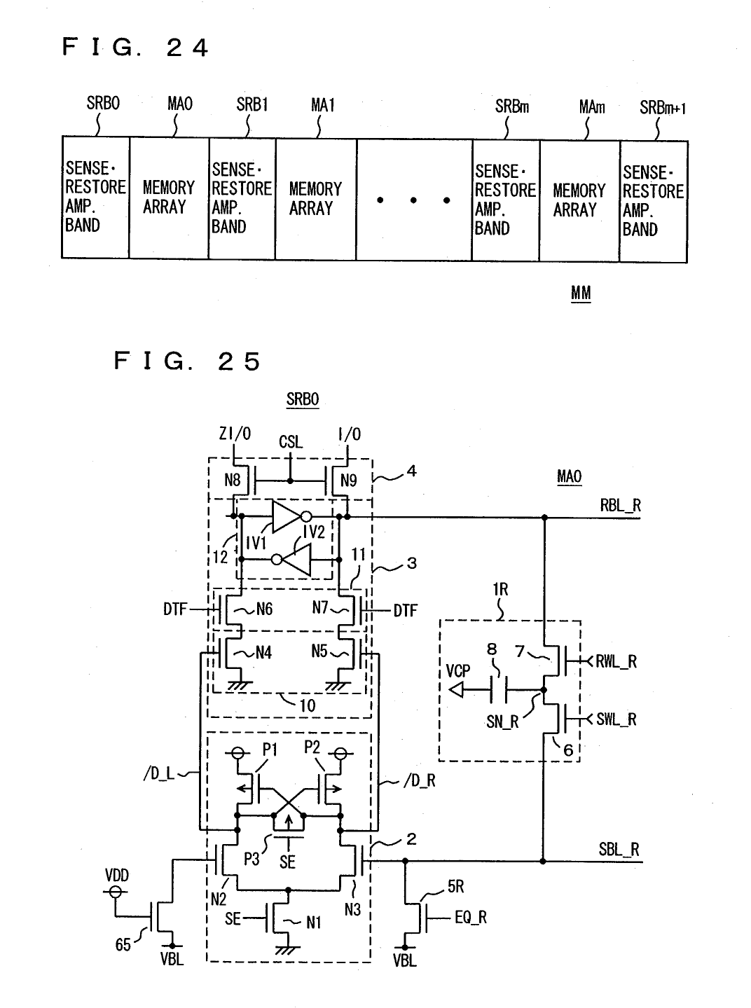

FIG. 24 is a diagram schematically showing a configuration of one memory mat MM of a semiconductor memory device according to a ninth embodiment of the present invention. In FIG. 24, memory mat MM includes: memory arrays MA0 to MA1 each having a plurality of memory cells arranged in rows and columns; sense-restore amplifier bands SRB1 to SRBm arranged between memory arrays MA0 to MA1; and sense-restore amplifier bands SRB0 and SRBm+1 arranged outside memory arrays MA0 and MAm.

In memory mat MM shown in FIG. 24, sense-restore amplifiers are alternately arranged on both sides of each of memory arrays MA0 to MA1. That is, sense-restore amplifiers are arranged in an alternatively arranged, shared sense-restore configuration. For the configurations of a sense amplifier and a restore amplifier shared between adjacent memory arrays, any one of the configurations of the sharing by memory arrays shown in the third to fifth embodiments may be employed.

Sense-restore amplifier bands SRB0 and SRBm+1 are arranged on respective ends of memory mat, and each are coupled to sense/restore bit. lines only on one side thereof. Bit lines are coupled to the gates of MOS transistors at input differential stage of a sense amplifier. Therefore, when sense bit lines are equalized to equalize voltage VBL, arrangement of sense amplifiers and restore amplifiers of sense-restore amplifier bands SRB0 and SRBm+1 arranged on both ends of the memory mat is different from arrangement of sense amplifiers and restore amplifiers of the other sense-restore amplifier bands SRB1 to SRBm.

FIG. 25 is a diagram showing a configuration of a part associated with one sense amplifier and one restore amplifier of sense-restore amplifier band SRB0 shown in FIG. 24. In sense-restore amplifier SRBm +1, the configuration reverse in left and right relation to the configuration shown in FIG. 5 is provided.

In FIG. 25, in sense amplifier 2, the gate of MOS transistor N3 at the differential stage thereof is connected to sense bit line SBL_R and an equalize transistor 5R rendered conductive in response to equalize instruction signal EQ_R is provided to sense bit line SBR_R. On the other hand, since no memory array exists in a region on the left side of sense amplifier 2, a reference transistor 65 kept in on state at all times and transmitting equalize voltage VBL is connected to the gate of MOS transistor N2 of sense amplifier 2.

In restore amplifier 3, an output section of inverter IV1 of latch circuit 12 is connected to restore bit line RBL_R. The output section of inverter IV2 of latch circuit 12 is connected only to the input of inverter IV1 and no signal line corresponding to a restore bit line is provided to the input section of inverter IV1. A column select gate 4 is provided to the latch nodes of latch circuit 12. The other configuration is the same as the configuration shown in FIG. 1, the same reference symbols are attached to corresponding components and detailed descriptions thereof will not be repeated.

In sense amplifier 2, capacitance values connected to the gates of MOS transistors N2 and N3 are different from each other. Sense amplifier 2, however, performs only a differential amplification on potentials on the gates of MOS transistors N2 and N3, it can perform a correct sense operation even in a state where capacitance values of the sense input nodes thereof are in a non-equilibrium state, as far as read voltage VBL is applied at all times to the gate of MOS transistor N2.

Note that sense amplifier 2 is activated when the corresponding memory array MAO is selected. Likewise, equalize instruction signal EQ_R to equalize transistor 5R is deactivated when memory array MAO is selected.

Restore amplifier 3 merely receives and latches amplified data of sense amplifier 2 in response to transfer instruction signal DTF. Therefore, no problem occurs even if capacitance values of the latch nodes of latch circuit 12 is in non-equilibrium state. Specifically, complementary data are stored in the latch nodes of latch circuit 12. In the configuration shown in FIG. 25, a voltage level on the input node of inverter IV1 of latch circuit 12 is driven by differential stage 10 according to transfer data from sense amplifier 2, and then the latch nodes are driven by inverters IV12 and IV2. Thus, complementary data are correctly latched in latch circuit 12.

Furthermore, in data writing, even if the latch nodes of latch circuit 12 are coupled to internal data line I/O and ZI/O through column select gate 14 when column select signal CSL is in selected state, complementary data are transferred to the latch nodes of latch circuit 12 by write driver generating internal write data. Write data can be latched into latch circuit 12 with correctness.

Note that in data writing, inverter IV2 of latch circuit 12 may be set in output high impedance state when write instruction signal WE is in active state.

In the configuration shown in FIG. 24, an equalize transistor may be provided to restore bit line RBL_R and in this case, latch circuit 12 is set in output high impedance state when restore bit line equalize instruction signal is active.

According to this embodiment of the present invention, as described above, as for a sense amplifier arranged at an end of a memory mat, a reference transistor transmitting an equalize voltage is connected to the reference input node of the sense amplifier. Thus, even in a case where sense bit lines are provided only on one side of the sense amplifier, a sense reference voltage can be correctly applied to the sense amplifier input node.

Furthermore, as for restore amplifier, restore bit lines are correctly driven according to sense data from a corresponding sense amplifier even if restore bit lines are provided only on one side and load capacitance values of the latch nodes are in non-equilibrium state.

Furthermore, no necessity arises for providing dummy bit lines and dummy cells to equilibrate the loads on the nodes of a sense amplifier and of a restore amplifier, thereby enabling suppression of increase in array area.

Tenth Embodiment

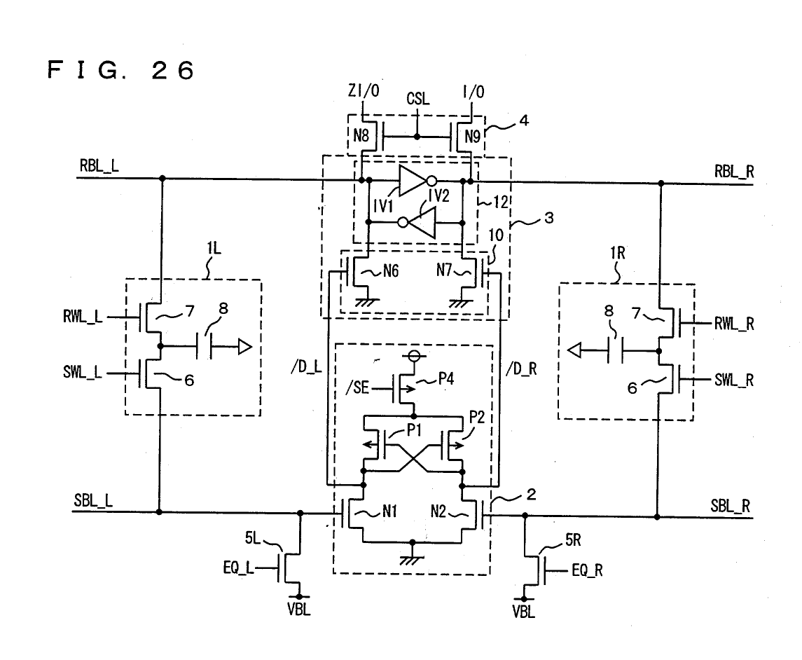

FIG. 26 is a diagram showing a configuration of a main part of a semiconductor memory device according to a tenth embodiment of the present invention. The configuration shown in FIG. 26 is different from the configuration shown in FIG. 1 in the configurations of sense amplifier 2 and restore amplifier 3. Sense amplifier 2 includes: N-channel MOS transistors N1 and N2 having gates connected to respective sense bit lines SBL_R and SBL_L and constituting a differential stage; P-channel MOS transistors P1 and P2 having gates and drains cross coupled; and a P-channel MOS transistor P4, rendered conductive in response to activation of sense amplifier activation signal /SE, for supplying power supply voltage to the sources of MOS transistors P1 and P2. MOS transistors N1 and N2 have sources coupled to ground node and maintain conductive normally.

In the configuration of sense amplifier 2, when sense amplifier activation signal /SE is in a non-active state, MOS transistor P4 is in an off state and MOS transistors N1 and N2 receive equalize voltage at their gates and sense output lines /D_R and /D_L are precharged to ground voltage level.

Restore amplifier 3 includes differential stage 10 differentially amplifying signals on sense output lines /D_R and /D_L, and latch circuit 12 latching output signals of differential stage 10.

Since sense output lines /D_R and /D_L are precharged to ground voltage level in standby state, N-channel MOS transistors N7 and N6 included in differential stage 10 is non-conductive in the standby state. When sense amplifier 2 is activated to change the voltage levels on sense output lines /D_R and /D_L according to output data of sense amplifier 2, one of sense output lines /D_R and /D_L attains H level and in response, the latch nodes of latch circuit 12 are set to voltage levels corresponding to output data of sense amplifier 2. When a sense operation of sense amplifier 2 is completed, latch circuit 12 in restore amplifier 3 latches output data of sense amplifier 2. Therefore, there is especially no need to provide transfer gates for controlling data transfer to latch circuit 12 from sense amplifier 2, thereby enabling reduction in layout area of restore sense amplifiers. In addition, control of data transfer to restore amplifier 3 from sense amplifier 2 is not required to simplify the control.

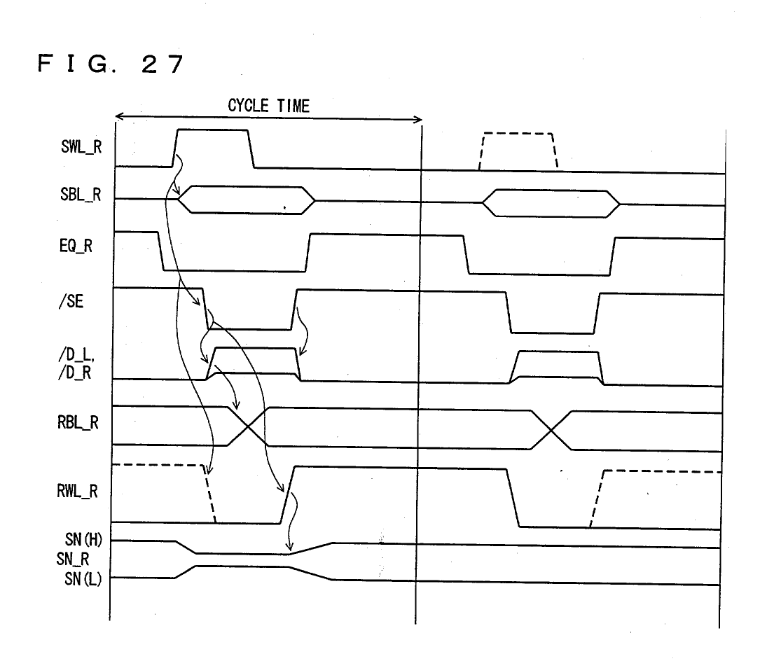

FIG. 27 is a signal waveform diagram representing operations of a semiconductor memory device shown in FIG. 26. In FIG. 27, there is shown operating waveforms in a case where memory cell 1R in the right side is selected. In the standby state, sense amplifier activation signal /SE is at H level and sense amplifier is in an inactive state to hold sense output lines /D_R and /D_L both at ground voltage level. Therefore, in restore amplifier 3, transfer gate 10 is in a non-conductive state and latch circuit 12 latches data read out in the previous cycle.

Furthermore, equalize instruction signals EQ_R and EQ_L are both at H level and sense bit lines SBL_R and SBL_L are equalized to equalize voltage VBL.

When an active cycle in which a memory cell is selected starts, equalize instruction signal EQ_R attains ground voltage level to complete an equalize operation on sense bit line SBL_R. Equalize instruction signal EQ_L for sense bit line SBL_L maintains the active state.

Then, sense word line SWL_R is selected and storage data of memory cell 1R is transmitted onto sense bit line SBL_R to change a voltage level thereon.

Then, sense amplifier activation signal /SE is activated. Restore word line RWL in selected state at that time is driven to a non-selected state prior to activation of sense amplifier activation signal /SE. A timing of deactivation of the restore word line may be the same as that of activation of sense amplifier activation signal /SE.

When sense amplifier activation signal /SE is activated, voltage levels on sense output lines /D_R and /D_L are set to voltage levels corresponding to sense data. A sense output line at the higher potential of sense output lines /D_R and /D_L is driven almost up to power supply voltage level.

When one of sense output lines /D_R and /D_L attains high level, of MOS transistors N6 ad N7 in differential stage 10 of restore amplifier 3, the MOS transistor receiving a signal at high level at the gate thereof turns conductive and in response, potentials at the latch nodes of latch circuit 12 are set to potential levels corresponding to sense data transmitted through differential stage 10. In FIG. 27, there is shown, by way of example, the state where latch data in latch circuit 12 is inverted.

Then, when a latch operation of latch circuit 12 is completed, restore word line RWL_R is selected to rewrite data to storage node SN_R of selected memory cell 1R.

Sense word line SWL_R is activated after completion of data transfer to restore amplifier 3 from sense amplifier 2. In restore amplifier 3, no transfer gates are provided for transferring data to restore amplifier 3 from sense amplifier 2. Therefore, sense word line SWL_R may be deactivated at a timing faster than activation of restore word line RWL_R.

After data transfer to restore amplifier 3, sense amplifier activation signal /SE is deactivated, and equalize instruction signal EQ_R is activated. Deactivation of sense amplifier activation signal /SE may be made at the same timing as activation of restore word line RWL_R, or restore word line RWL_R may be activated at a timing later than deactivation of sense amplifier activation signal /SE.

When sense amplifier activation signal /SE is deactivated, sense output lines /D_R and /D_L both attain ground voltage level, and in restore amplifier 3, MOS transistors N6 and N7 at differential stage 10 enter off state to isolate sense output lines /D_R and /D_L from latch circuit 12. Then, a column select operation is performed while restore word line RWL_R is in selected state, and data access for restore amplifier 3 is made.

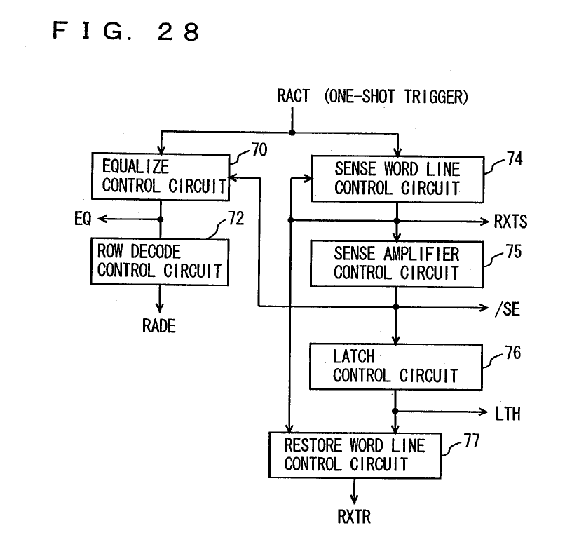

FIG. 28 is a diagram showing an example of a configuration of a part for generating control signals shown in FIG. 26. A configuration of the row related select circuit is the same as the configuration shown in FIG. 4 and a restore word line address designating signal is latched by a latch circuit provided at a preceding stage of a restore word line driver.

In FIG. 28, a row related control signal generating circuit includes: an equalize control circuit 70 for deactivating equalize instruction signal EQ in response to activation of row access instruction signal RACT generated in the form of a one shot pulse; and a row decode control circuit 72 activating row address decode enable signal RADE in response to deactivation of equalize instruction signal EQ. Row address decode enable signal RADE from row decode control circuit 72 is applied to row decoder 20 shown in FIG. 4.

When a row access instruction is applied, row access instruction signal RACT is generated as a trigger pulse of one shot by, for example, a command decoder. In a case of this construction, successive access can be ensured without especially applying a precharge command for driving a memory array into a precharged state. In order to drive a restore word line in selected state to an inactive state, a precharge command may also be applied.

The row related control signal generating circuit. further includes: a sense word line control circuit 74 for activating sense word line drive timing signal RXTS in response to activation of row access instruction signal RACT; a sense amplifier control circuit 75 for activating sense amplifier activation signal /SE in response to activation of sense word line drive timing signal RXTS; a latch control circuit 76 for activating latch instruction signal LTH in response to activation of sense amplifier activation signal /SE; and a restore word line control circuit 77 for deactivating refresh word line drive timing signal RXTR in response to activation of sense word line drive timing signal RXTS, and for activating restore word line drive timing signal RVTR in response to activation of latch instruction signal LTH.

Sense word line control circuit 74 deactivates sense word line drive timing signal RXTS after an elapse of a prescribed period elapses since activation of sense word line drive timing signal RXTS.

On the other hand, equalize control circuit 70 activates equalize instruction signal EQ in response to deactivation of sense amplifier activation signal /SE and row decode control circuit 72 deactivates row address decode enable signal RADE in response to equalize instruction signal REQ.

Sense amplifier control circuit 75 activates sense amplifier activation signal /SE after an elapse of a prescribed period elapses since the activation of sense word line drive timing signal RXTS. Sense amplifier control circuit 75 further deactivates sense amplifier activation signal /SE after an elapse of a prescribed period elapses since deactivation of sense word line drive timing signal RXTS.

Latch control circuit 76 generates latch instruction signal LTH in response to activation of sense amplifier activation signal /SE, to cause a latch circuit provided to a restore word line select circuit to take in and latch a word line designation signal outputted by row decoder. Latch control circuit 76 may activate latch instruction signal LTH at a timing faster than activation of sense amplifier activation signal /SE in response to activation of sense word line drive timing signal RXTS.

Restore word line control circuit 77 deactivates restore word line drive timing signal RSTR after an elapse of a prescribed period since activation of sense word line drive timing signal RXTS and then, when latch instruction signal is activated, again it activates restore word line drive timing signal RXTR. Thereby, restore word line drive timing signal RXTR is deactivated at a timing prior to or at the same timing as activation of sense amplifier and again activated after deactivation of sense amplifier activation signal /SE.

Modification

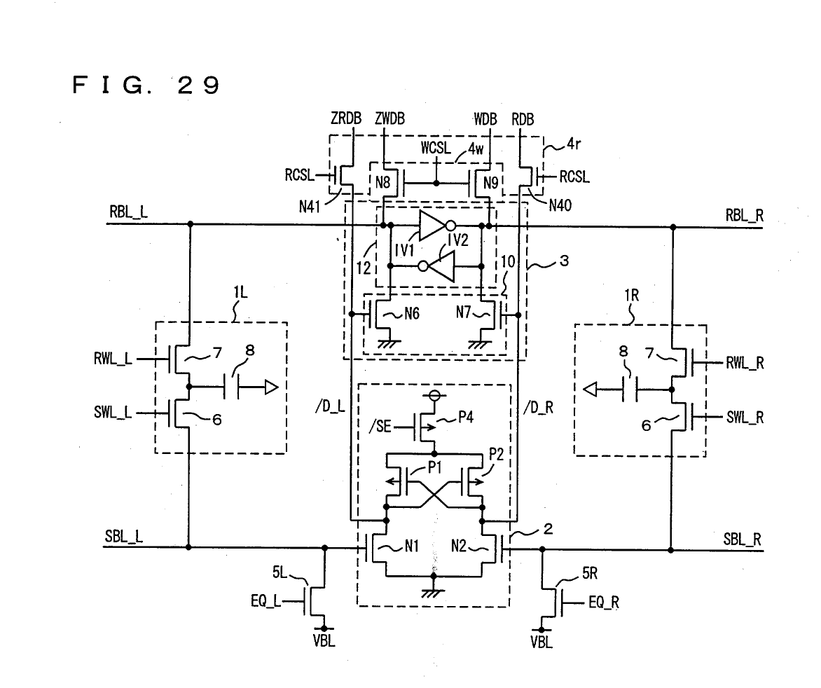

FIG. 29 is a diagram showing a modification of the tenth embodiment of the present invention. In FIG. 29, a column select circuit includes: a write column select gate 4w selectively rendered conductive in response to a write column select signal WCSL; and a read column select gate 4r selectively rendered conductive in response to a read column select signal RCSL.

Write column select gate 4w includes N-channel MOS transistors N8 and N9 coupling the latch nodes (input/output nodes of inverter IV1) of latch circuit 12 to internal write data bus lines WDB and ZWDB in response to activation of write column select signal WCSL.

Read column select gate 4r includes N-channel MOS transistors N40 and N41 electrically coupling sense output lines /D_R and /D_L to respective internal read data bus lines RDB and ZRDB in response to activation of write column select signal RCSL.

Due to read column select gate 4r provided to sense output lines /D_R and /D_L, a data read operation can be performed prior to completion of a latch operation by restore amplifier 3, thereby enabling a high speed access.

Note that a pull up element is usually provided to each of internal read data bus lines RDB and ZRDB in order to transmit a signal of a small amplitude to a preamplifier. Therefore, it is not required to drive sense output lines /D_R and /D_L of sense amplifier 2 to the CMOS level, thereby enabling high speed transmission of internal read data to the preamplifier at the subsequent stage.

According to the tenth embodiment of the present invention, as described above, sense output signal lines are precharged to ground voltage level. No transfer gates are required for transferring data to the restore amplifier from the sense amplifier, thereby reduction in layout area of sense/restore amplifiers.

Sense amplifiers and restore amplifiers described in the first to tenth embodiments each can be of any construction, provided that data on sense bit lines are sensed and sense data are latched by a restore amplifier and the data is rewritten to a memory cell through restore bit lines.

Furthermore, in the configurations shown in FIGS. 26 and 29, equalize voltage VBL on sense bit lines has only to be a voltage level at which MOS transistors N1 and N2 of sense amplifier 2 are conductive, and may be a voltage level of the intermediate voltage or higher. Therefore, in a case where equalize voltage VBL is power supply voltage level VDD, by using a dummy cell to transmit storage data of the dummy cell to a reference sense bit line to generate a reference potential, a correct sense operation can be performed.

Eleventh Embodiment

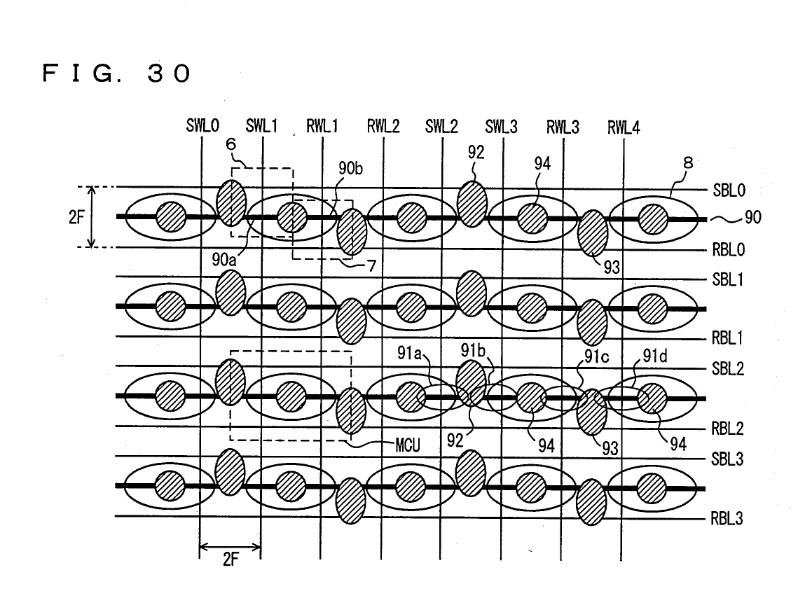

FIG. 30 is a diagram schematically showing a layout of a memory array according to an eleventh embodiment of the present invention. In FIG. 30, sense word lines SWL and restore word lines RWL are alternatively arranged, with two word lines of the same kind being a unit. Reference symbols SWL and RWL are used to genericly indicate the sense word lines and all the restore word lines, respectively. In FIG. 30, sense word lines SWL0 to SWL3 and restore word lines RW1 to RWL4 are depicted as representatives.

Active regions 90 continuously extending in a column direction are arranged at a prescribed interval in a row direction. Memory cell transistors (access transistors) are formed with active regions 90. In the following description, an active region is defined to be an impurity injection (diffusion) region, including a channel region of an access transistor.

Sense bit line SBL and restore bit line RBL are arranged at respective both sides of each active region 90 in parallel to active region 90. Reference symbols SBL and RBL are used to genericly indicate the sense bit lines and all the restore bit lines, respectively. In FIG. 30, sense bit lines SBL0 to SBL3 and restore bit lines RBL0 to RBL3 are depicted as representatives.

In the layout shown in FIG. 30, sense bit lines SBL and restore bit lines RBL extending in row direction are alternately arranged to each other. A specific layout of sense bit lines SBL and restore bit lines RBL will be detailed later.

In correspondence to active regions 90, first connection conductors 92 for connecting sense access transistors 7 to sense bit lines SBL are arranged at prescribed intervals in the column direction. Furthermore, second connection conductors 93 for connecting access transistors 7 to restore bit lines RBL are arranged at prescribed intervals in column direction. First connection conductors 92 each are arranged between sense word lines in a pair, while second connection conductors 93 each are arranged between restore word lines in a pair.

A connection conductor 94 connected to active region 90 is provided in a region between first and second connection conductors 92 and 93. Connection conductors 94 each are provided for connecting a storage electrode node of a memory capacitor 8 to an active region of an access transistor. Here, as a structure of memory capacitor 8, a stacked capacitor structure is assumed.

Sense access transistor 6 can be formed of first connection conductor 92, active region 90a and third connection conductor 94. Restore access transistor 7 is formed of third connection conductor 94, active region 90b and second connection conductor 93.

First connection conductor 92 is shared by sense access transistors of memory cells adjacent in column direction and second connection conductor 93 is shared by restore access transistors of memory cells adjacent in column direction. One memory cell MC is formed of memory capacitor 8, sense access transistor 6 and restore access transistor 7. Therefore, in FIG. 30, one memory cell is formed by memory cell unit MCU.

Connection conductor 92 is shared by adjacent two sense access transistors and second connection conductor 93 is shared by adjacent two restore access transistors, thereby enabling significant reduction in layout area, as compared with a construction in which connection conductors are provided to individual transistors.

Since first connection conductor 92 connecting sense access transistor 6 and sense bit line SBL to each other is shared by adjacent memory cell units, transistor active regions for adjacent two restore access transistors 91a and 91b can be laid out into a continuous region without disconnection. Similarly, since connection conductor 93 is shared by restore access transistors 91c and 91d, transistor active regions for restore access transistors 91c and 91d can be laid out into a continuous region without disconnection.

Furthermore, connection conductor 94 connecting memory capacitor 8 to a storage node is also shared by sense access transistor 91b and restore access transistor 91c, and transistor active regions for sense access transistor 91b and restore access transistor 91c can be continuously extended. Therefore, active regions of access transistors arranged in alignment in the column direction are all formed into a continuous active region, and the transistor active region can be arranged extending in a straight line along the column direction. Therefore, a region isolating active regions is only a region isolating adjacent active regions 90 in the row direction. There is no region where an active region protrudes in the row direction, and thereby a layout of the active regions is facilitated and furthermore, fine processing of access transistors can be extremely readily done.

In active region 90, if an isolation region is provided between memory cells adjacent in the column direction, micro-processing of a memory cell is difficult because of the presence of the isolation region placed between adjacent memory cells in the column direction. However, by extending active region 90 continuously in the column direction, considering of such isolation regions in the column direction is not needed, but consideration is required only for isolation regions in the row direction, thereby facilitating isolation between active regions 90 and enabling microprocessing.

In a case where a bit line pitch (a spacing between adjacent bit lines) is 2F and a word line pitch (a pitch between adjacent word lines) is 2F, an occupancy area of a memory cell unit MCU is given by 4F×4F. Here, F indicates the minimum design size.

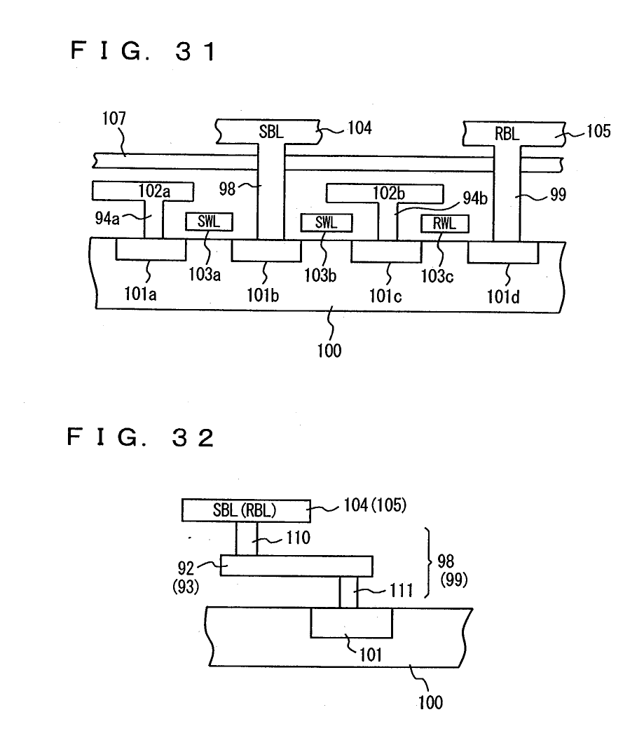

FIG. 31 is a diagram schematically showing a sectional structure of a memory cell of the layout shown in FIG. 30. In FIG. 31, impurity regions 101a to 111d are formed spaced apart from each other on a surface of a semiconductor substrate region 100. Impurity regions 101a to 101d are included in active region 90. In formation of active region 90, impurity implantation is performed with word lines (sense word lines and restore word lines) used as a mask, to form impurity regions, and therefore, active region 90 includes channel regions between impurity regions 101a to 101d. To the channel regions, generally, impurity implantation is performed in order to adjust threshold voltages of the access transistors.

Impurity region 101a is connected to a storage node electrode 101a through a connection conductor 94a. Impurity region 101b is connected to a conductive interconnection line 104 serving as sense bit line SBL through a contact 98 containing connection conductor 92. Impurity region 101c is connected to a storage node electrode 102b through a connection conductor 94b. Impurity region 10 id is connected to a conductive interconnection line 105 serving as restore bit line RBL through a contact 99 containing connection conductor 93. Description will be later given of construction of contacts 98 and 99.

A cell plate electrode layer 107 is formed facing storage node electrodes 102a and 102b in an upper layer above storage node electrodes 102a and 102b.

A conductive interconnection line 103a serving as sense word line SWL is formed on a substrate region surface between impurity regions 101a and 101b with a gate insulating film not shown interposed. A conductive interconnection line 103b serving as sense word line SWL is formed on a substrate region surface between impurity regions 101b and 101c with a gate insulating film not shown interposed. A conductive interconnection line 103c serving as sense word line SWL is formed on a substrate region surface between impurity regions 101c and 101d with a gate insulating film not shown interposed.

As shown in FIG. 31, an element isolation film for isolation between memory cells is not to place, and therefore, the access transistors can be consecutively formed.

Note that in the construction shown in FIG. 31, sense bit line SBL and restore bit line RBL may be formed with conductive interconnection lines in the same interconnection layer, or may be formed with conductive interconnection lines in different interconnection layers. In the construction shown in FIG. 31, conductive interconnection line 103 serving as sense bit line SBL and conductive interconnection line 105 serving as restore bit line RBL are formed in an upper layer above cell plate electrode 107, thus achieving a so-called CUB (capacitor under bit line) structure. As a memory capacitor structure, however, a memory capacitor with a so-called COB (capacitor over bit line) structure may be employed in which sense bit line and restore bit line are formed in a lower layer under storage node electrode layer 102a and 102b. Furthermore, another structure may be employed in which sense bit line SBL and restore bit line RBL are formed in different interconnection layers sandwiching cell plate electrode layer 107.

FIG. 32 is a diagram schematically showing a sectional structure of a connection section between a bit line (sense bit line and restore bit line) and an active region, using a connection conductor. In FIG. 32, conductive interconnection line 104 serving as sense bit line SBL is connected to connection conductor 92 through a contact conductor 110. Connection conductor 92 extends far onto an active region in the row direction and is connected to impurity region 101 through a contact conductor 111. A contact 98 shown in FIG. 31 is formed of contact conductors 110 and 111 and connection conductor 92. Contact 99 shown in FIG. 31 is formed of contact conductor 110 to conductive interconnection line 105 of restore bit line RBL, connection conductor 93, and contact conductor 111 to connection conductor 93.

Therefore, by use of connection conductors 92 and 93, sense bit line SBL and restore bit line RBL can also be electrically connected to impurity region 101 of active region 90 with certainty even in a construction in which active region 90 and bit lines SBL and RBL are arranged extending in parallel to each other in the column direction.

According to the eleventh embodiment of the present invention, as described above, active regions are arranged extending continuously in the column direction and connection conductors connecting an active region to a sense bit line and to a restore bit line are formed so as to be shared between adjacent memory cells. Miniaturization process can be readily applied to an active region, thereby enabling reduction in layout area of a memory array.

Note that in the layout of a memory cell shown in FIG. 30, the arrangement of memory cells is of high density arrangement suitable for the open bit line configuration. In the construction in which one bit data is stored by two memory cells, however, bit lines are arranged in the folded bit line configuration. In the case where one bit data is stored with one memory cell, bit lines are arranged in the open bit line configuration.

Twelfth Embodiment

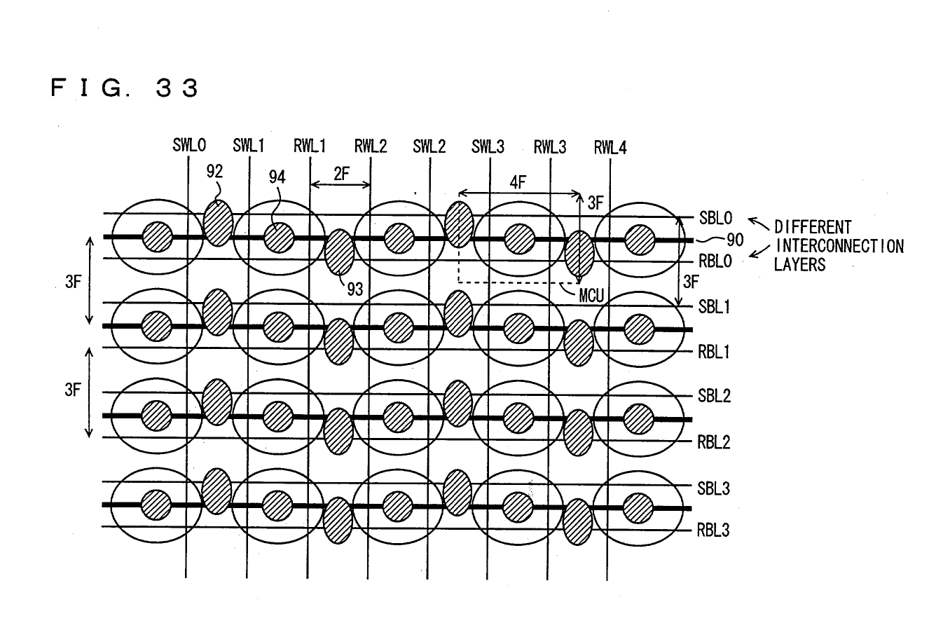

FIG. 33 is a diagram schematically showing a layout of a memory array of a semiconductor memory device according to an twelfth embodiment of the present invention. In FIG. 33, a layout of memory cells is the same as the layout shown in FIG. 30. That is, active region 90 is arranged continuously extending linearly along column direction and sense word lines SWL and restore word lines RWL are alternatively arranged with two lines being a unit. Sense bit lines SBL and restore bit lines RBL are arranged alternately to each other in the row direction. A word pitch (a pitch between adjacent word lines including sense word lines and restore word lines) is 2F. On the other hand, a pitch between sense bit lines is 3F and similarly, a pitch between restore bit lines RBL is 3F. In this case, therefore, a layout area of a memory cell unit MCU constructing a memory cell is 4F×3F=12F\hat{ }2. Here, a symbol A indicates a power, and “F\hat{ }2” is the same as “F times F”.

Sense bit line SBL and restore bit line RBL are formed of conductive interconnection lines in different interconnection layers. Therefore, a pitch between sense bit lines can be set to 3F smaller than 4F.

In a standard DRAM, a fundamental construction unit serving as one memory cell is 2F in length and 4F in width and a layout area thereof is given by 8F\hat{ }2. Accordingly, a cell density is reduced to 2/3 times, as compared with that of standard DRAM. However, an area of the fundamental construction unit (memory cell unit) is 1.5 times as large as that of standard DRAM, thereby enabling increase in capacitance value of a memory cell capacitor with ease. Furthermore, more electric charges can be accumulated in a memory cell, with the result of stabilization of a DRAM operation.

An array arrangement shown in FIG. 33 is suitable for the open bit line configuration as shown in, for example, the first embodiment. Specifically, a pitch between sense bit lines SBL is 3F, being 1.5 times as large as a bit line pitch 2F of standard DRAM. Therefore, a capacitance coupling between adjacent bit lines is small, thereby enabling an enhancement in noise immunity between adjacent bit lines, generally regarded as a weak point of the open bit line configuration.

Sense bit lines SBL and restore bit lines RBL are alternately arranged in the row direction and sense bit line SBL is sandwiched between restore bit lines RBL. A voltage level on restore bit line is set to ground voltage level or power supply voltage level by a restore amplifier at the start of a sense operation. Therefore, restore bit lines RBL functions as shield interconnection to sense bit line SBL in a sense operation, and the noise otherwise caused by coupling capacitance between sense bit lines can be suppressed, to enable correct reading and sensing operation on memory cell data.

Pitches of sense bit lines SBL, restore bit lines RBL and active regions 90 are all 3F. This is because one active region 90 and one restore bit line RBL are provided for one memory cell in the row direction similarly to sense bit line SBL.

Therefore, since the pitches are larger compared with the case where bit line pitches is 2F as in standard DRAM cell, a processing margin in micro-processing can be made sufficiently large, and micro-processing can be performed with ease.

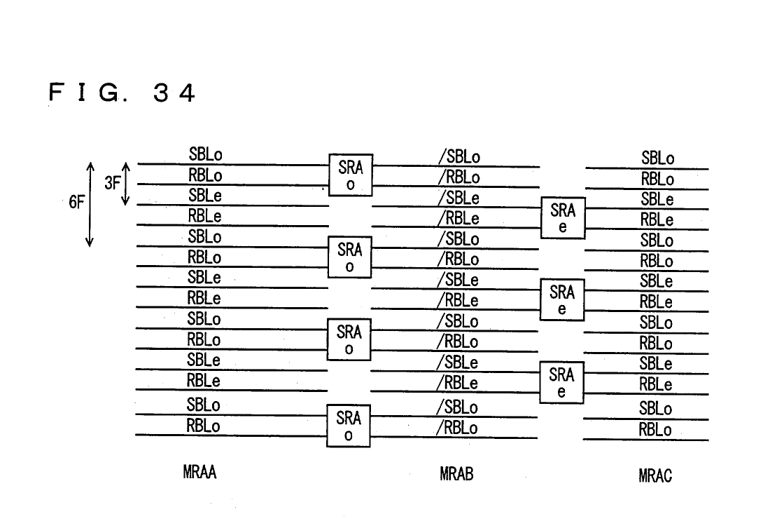

FIG. 34 is a diagram schematically showing arrangement of sense/restore amplifiers in the memory cell layout shown in FIG. 33. In FIG. 34, three memory arrays MRAA, MRAB and MRAC are arranged in the column direction. In memory arrays MRAA, MRAB and MRAC, a pair of an odd-numbered sense bit line SBLo and an odd-numbered restore bit line RBLo and a pair of an even-numbered sense bit line SBLe and an even-numbered restore bit line SBLe are alternately arranged at a pitch of 3F. In a sense/restore amplifier band between memory arrays MRAA and MRAB, an odd-numbered sense/restore amplifier SLAo is provided to odd-numbered sense bit lines SBLo and /SBLo and odd-numbered restore bit lines RBLo and /RNLo.

In a sense/restore amplifier band between memory arrays MRAB and MRAC, an even-numbered sense/restore amplifier SLAe is provided to even-numbered sense bit lines SBLe and /SBLe and even-numbered restore bit lines RBLe and /RNLe.

Therefore, as shown in FIG. 34, by providing sense/restore amplifiers alternately on both sides of each of memory arrays MRAA to MRAC, a pitch between sense/restore amplifiers SRAo and SRAe can be set to 6F with a pitch between sense bit lines and restore bit lines being 3F. Thus, sense/restore amplifiers can be placed with sufficient margin. In a case of standard DRAM, a bit line pitch is 2F, and in the case of alternately arranged sense amplifiers, a pitch between sense amplifiers is 8F because it is required to provide one sense amplifier to four bit lines. Therefore, in a case of the alternately arranged sense/restore amplifiers as shown in FIG. 34, though a pitch is somewhat smaller than the pitch between alternately arranged sense amplifiers in the standard DRAM, sense/restore amplifiers can be arranged with a sufficient margin.

In the arrangement of alternately arranged sense/restore amplifiers shown in FIG. 34, memory cell data is read out onto sense bit lines of a selected memory array, and a memory array sharing a sense/restore amplifier with the selected memory array has the bit lines maintained in a precharged state. As for restore bit lines, how to change the voltages on restore bit lines of a selected memory array is different depending on how to connect the restore amplifier to restore bit lines: a restore bit line isolation gate is provided; and a restore bit line is directly connected to a restore amplifier. In a selected memory array, voltage levels on restore bit lines change according to sensed data.

Note that any one of restore bit lines RBL and sense bit lines SBL may be provided above the other. Since lower layer conductive interconnection lines are higher in degree of evenness than those in an upper interconnection layer, patterning of the lower layer interconnection lines can be performed more easily. Therefore, in the lower layer, conductive interconnection lines with a desired property can be formed with ease without receiving an influence such as a pattern deviation. Therefore, it is sufficient to determine which of sense bit lines and restore bit lines is formed in an upper interconnection layer appropriately according to a property required for the sense bit lines and restore bit lines.

According to the twelfth embodiment of the present invention, as described above, pitches between sense bit lines and restore bit lines are set to be larger than a word line pitch. Memory cells can be placed with a margin and furthermore, a capacitance value of a memory cell capacitor can be increased. By the use of the open bit line configuration, sense/restore amplifiers can be arranged in alternate arrangement, which makes it possible to arrange sense/restore amplifiers with a margin. Furthermore, restore bit lines and sense bit lines are formed in different interconnection layers, thereby enabling sense bit lines and restore bit lines at a pitch larger than a pitch between word lines.

Thirteenth Embodiment

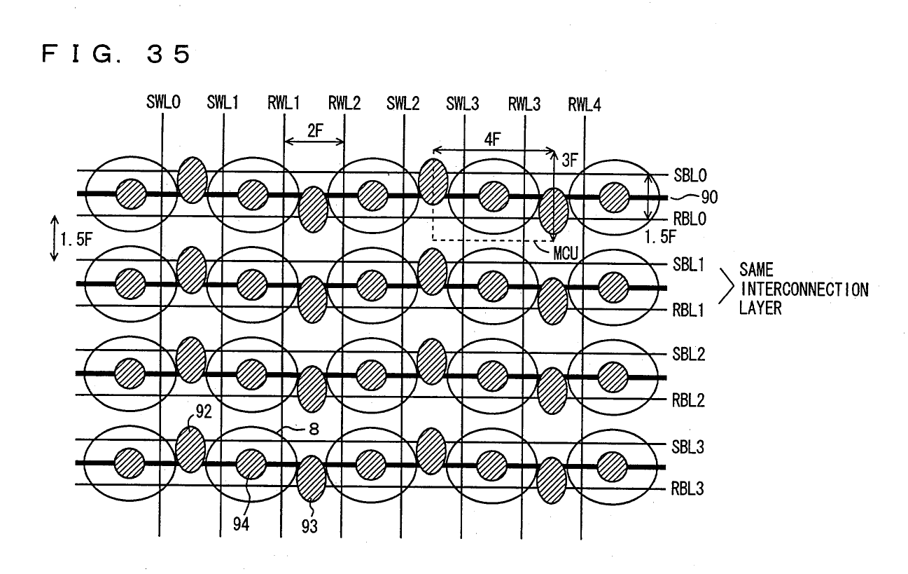

FIG. 35 is a diagram schematically showing a layout of the memory array according to a thirteenth embodiment of the present invention. In a layout shown in FIG. 35 as well, active regions 90 are arranged continuously extending in a straight line form along the column direction. Furthermore, connection conductors 92 each for connecting an active region to a sense bit line SBL and connection conductors 93 each for connecting an active region to restore bit line RBL are alternately arranged at prescribed pitches in the column direction. Connection conductor 94 for connecting an active region 90 to a capacitor storage node is provided between connection conductors 92 and 93.

In the memory cell layout shown in FIG. 35, sense bit lines SBL and restore bit lines RBL are formed in the same interconnection layer. A layout area of memory cell unit MCU is 4F×3F. Two word lines are provided in one memory cell unit MCU and one sense bit line SBL and one restore bit line RBL are provided in one memory cell unit MCU. Therefore, a pitch between word lines is 2F, while a pitch between bit lines is 1.5F. Here, the “bit line pitch” genericly indicates a pitch or interval between adjacent bit lines including sense bit lines and restore bit lines. A pitch between sense bit lines SBL is, therefore, 3F and a pitch between restore word lines is 3F.

In the layout of the memory array shown in FIG. 35, the pitch between bit lines is 1.5F and the layout is to some extent more disadvantageous in terms of micro-processing and noise between bit lines, as compared to the layout shown in FIG. 33. However, sense bit lines and restore bit lines are alternately arranged in this layout as well and are conductive interconnection lines in the same interconnection layer. Therefore, restore bit lines can function as shield interconnection for sense bit lines and inter-bit line noise of sense bit lines can be reduced, thereby enabling correct transmission of read voltage of a small amplitude.

As for restore bit lines, after data amplified by a sense amplifier is latched, restore bit line RBL is driven according to latch data in a latch circuit. Therefore, since restore bit lines are driven by latch circuits, an influence of noise caused between restore bit lines can be suppressed to drive restore bit lines according to latch data with correctness. Even if noise occurs on a sense bit line, restoration can be correctly performed on a memory cell by the restore amplifier.

In the memory array layout shown in FIG. 35, an area of memory cell capacitor 8 can be larger, similarly to a memory capacitor in the twelfth embodiment shown in FIG. 33, thereby enabling accumulation of sufficient amount of electric charges in a storage node to ensure a stable memory operation.

Especially, in the layout shown in FIG. 35, since sense bit lines SBL and restore bit lines RBL are formed using conductive interconnection lines in the same interconnection layer and the number of interconnection layers decreases, which can reduce a fabrication cost.

In the layout shown in FIG. 35 as well, bit lines are arranged in the open bit line configuration and an arrangement of the alternately arranged shared sense/restore amplifier configuration is used similarly to the arrangement shown in FIG. 34. A pitch of sense/restore amplifiers in this case is 6F, similar to the arrangement shown in FIG. 34.

According to the thirteenth embodiment of the present invention, as described above, since sense bit lines and restore bit lines are formed in the same interconnection layer and a bit line pitch is set smaller than a word line pitch. Thus, memory cells can be arranged at high density without reducing a capacitance value of a memory cell capacitor. Furthermore, the number of interconnection layers can be reduced to reduce a fabrication cost.

Fourteenth Embodiment

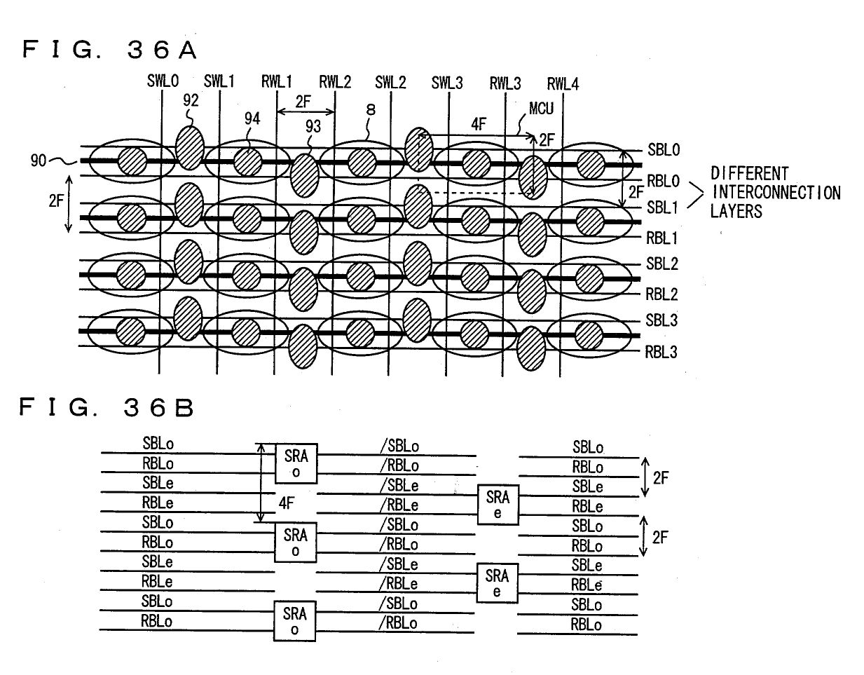

FIG. 36A is a diagram schematically showing a layout of memory cells according to a fourteenth embodiment. In the layout shown in FIG. 36A, arrangement of active regions 90 and connection conductors 92 to 94 are the same as that shown in FIG. 30. A word line pitch is 2F. Sense bit lines SBL and restore bit lines RBL are formed in different layers. A pitch between sense bit lines SBL is 2F and a pitch between restore bit lines RBL is also 2F. In this case, therefore, a layout area of a memory cell unit MCU is 4F×2F=8F\hat{ }2 and the same as a layout area of a normal DRAM cell. Therefore, an area of a memory cell capacitor is sufficiently secured to accumulate electric charges.

A pitch between sense bit lines SBL and between restore bit lines RBL is 2F and the same as a bit line pitch of a normal DRAM. Sense bit lines SBL and restore bit lines RBL are formed in different interconnection layers, sense bit lines SBL and restore bit lines RBL can be formed in a process similar to a fabrication process for a normal DRAM, and therefore, no problem arises in terms of fabrication process.

Since the open bit line configuration is employed, one memory capacitor 8 stores one bit data. Therefore, memory cells can be arranged at the same density as that of standard DRAM cells.

FIG. 36B is a diagram showing arrangement of sense/restore amplifiers in the layout shown in FIG. 36A. As shown in FIG. 36B, sense bit lines SBL and restore bit lines RBL are arranged in the open bit line configuration and a sense/restore amplifier band is arranged between two memory arrays. Sense/restore amplifiers SBAo corresponding to odd-numbered sense bit lines SBLo and odd-numbered restore bit lines RBLo are arranged in a sense/restore amplifier band in one side of one memory array. In a sense/restore amplifier band in the other side of the one memory array, sense/restore amplifiers SRAe corresponding to even-numbered sense bit lines SBLe and even-numbered restore bit lines RBLe are arranged. Sense/restore amplifiers SRAo and SRAe are alternately arranged in both sides of the memory array opposing to each other. In one sense/restore amplifier band, a sense/restore amplifier is arranged, with one sense bit line and one restore bit line placed between adjacent sense/restore amplifiers. Therefore, a pitch between sense/restore amplifiers SRAo and SRAe is 4F. In normal DRAM, a pitch between sense amplifiers is 8F in the alternately arranged sense amplifier configuration. However, sense bit lines and restore bit lines are formed in different interconnection layers and are arranged in the open bit line configuration, and therefore, sense/restore amplifiers can be arranged satisfactorily at a pitch of 4F.

According to the fourteenth embodiment of the present invention, as described above, a pitch between sense bit lines and restore bit lines is set at the same as a word line pitch. There can be realized a memory cell unit with the same area as a unit cell area of a standard DRAM, to achieve the memory cell unit area as in a standard DRAM, to implement a sufficiently large memory cell capacitor. Furthermore, by employing the open bit line configuration, the same cell density as in a standard DRAM can be achieved, thereby enabling high density arrangement of memory cells.

Fifteenth Embodiment

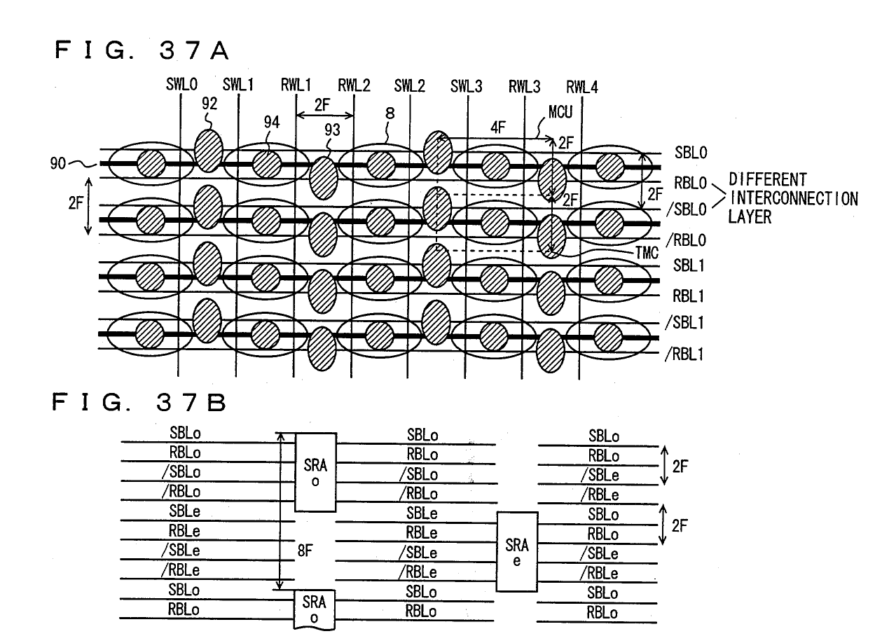

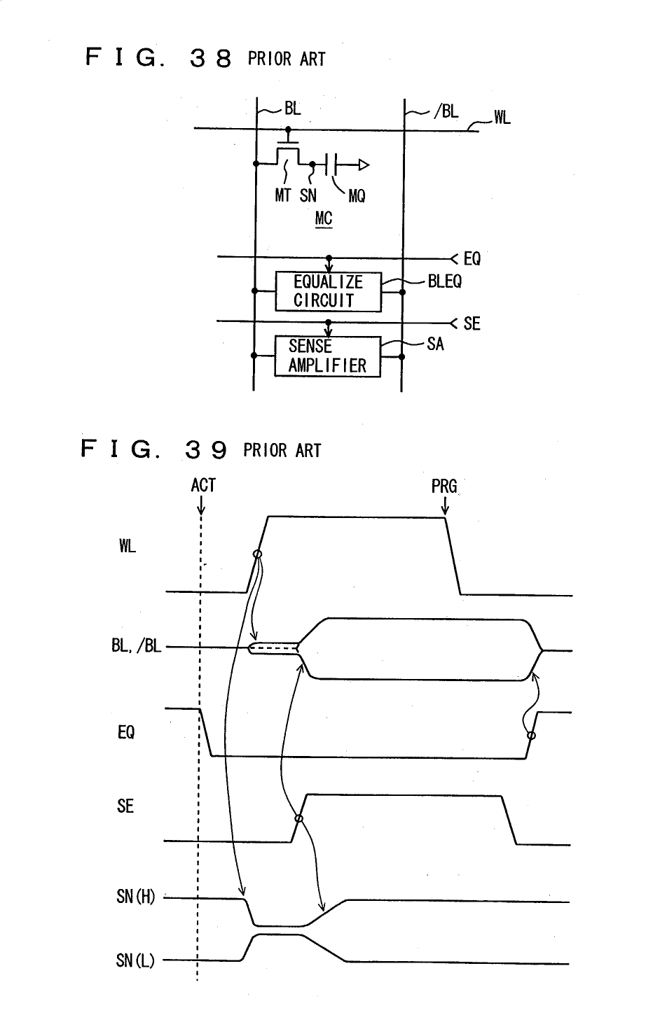

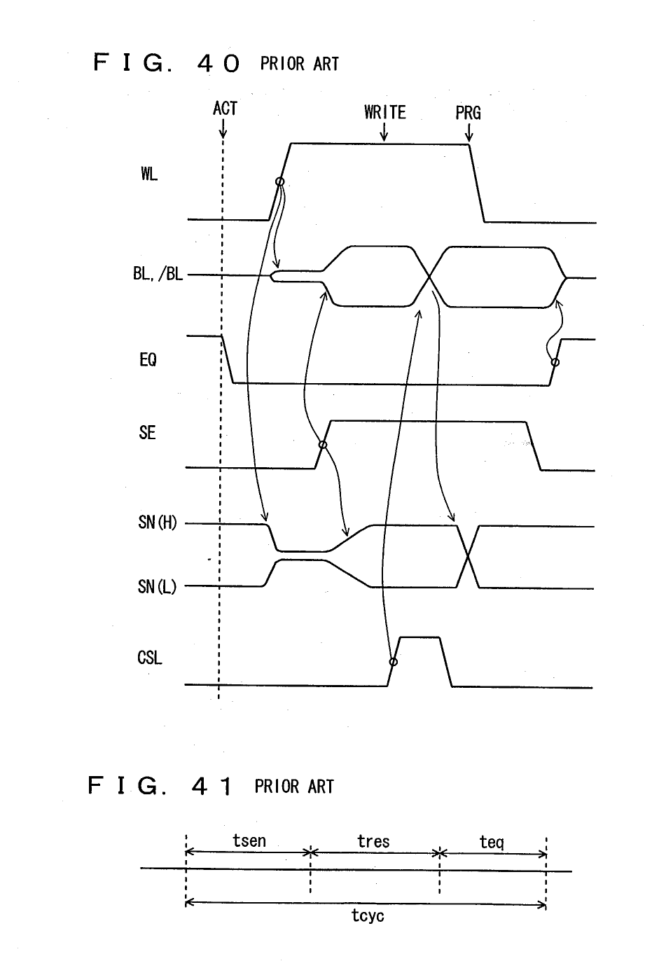

FIG. 37A is a diagram schematically showing a layout of memory cells according to a fifth embodiment of the present invention. The fundamental configuration of a layout shown in FIG. 37A is the same as the layout shown in FIG. 30. A word line pitch is 2F. Furthermore, sense bit lines and restore bit lines are alternately arranged. In the sense bit lines, however, complementary sense bit lines SBL and /SBL are alternately arranged and in addition, complementary restore bit lines RBL and /RBL are alternately arranged. In FIG. 37A, there are representatively shown sense bit lines SBL0 and SBL1 and sense bit lines /SBL0 and /SBL1. As for restore bit lines as well, there are representatively shown restore bit lines RBL0 and RBL1 and complementary restore bit lines /RBL0 and /RBL1.

Sense bit lines SBL and /SBL and restore bit lines RBL and /RBL are formed in different layers. A pitch between sense bit lines, or a spacing between sense bit lines complementary to each other is 2F and a pitch between restore bit lines (a spacing between restore bit lines complementary to each other) is also 2F.

In the memory cells arrangement shown in FIG. 37A, one bit data is stored by two memory cells. An area of a memory cell unit MCU is 4F×2F and the same as in a normal DRAM. However, since a fundamental unit region for storing one bit data is formed of two memory cell units MCU adjacent to each other in the row direction, an area of a unit construction TMC for storing one bit data is of 4F×4F. In the arrangement shown in FIG. 37A, a bit line arrangement that is strong against noise can be implemented making use of a so-called folded bit line configuration, enabling a correct sense operation.

FIG. 37B is a diagram schematically showing an example of the arrangement of sense/restore amplifiers in the layout shown in FIG. 37A. As shown in FIG. 37B, in one sense amplifier band, sense/restore amplifier SRAo is provided to odd-numbered sense bit line pair SBLo and /SBLo and odd-numbered restore bit line pair RBLo and /RBLo. In the other sense amplifier band, sense/restore amplifier SRAe is provided to even-numbered sense bit line pair SBLe and /SBLe and even-numbered restore bit line pair RBLe and /RBLe.

In one sense amplifier band, one sense/restore amplifier is provided to an even-numbered sense bit line pair and an even-numbered restore bit line pair, and in the other sense amplifier band, one sense/restore amplifier is provided to an odd-numbered sense bit line pair and an odd-numbered restore bit line pair. Therefore, a pitch between sense/restore amplifiers in one sense amplifier band is 8F, and sense/restore amplifiers can be arranged with margin.

In the fifteenth embodiment as well, sense bit lines SBL and /SBL and restore bit lines RBL and /RBL are formed in different interconnection layers. In this case, any of sense bit line pairs and restore bit line pairs may be formed in an upper layer. Which of sense bit line pairs and restore bit line pairs is formed in a upper layer has only to be determined appropriately according to properties required for the sense bit line pairs and the restore bit line pairs.

According to the fifteenth embodiment of the present invention, as described above, bit lines are arranged in the folded bit line configuration, one bit data is stored with two memory cells, and a pitch between sense bit lines and between restore bit lines is made the same as a word line pitch. A pitch between sense/restore amplifiers in an alternately arranged sense/restore amplifier configuration can be significantly made large.

Furthermore, one bit data is stored with two memory cells and data can be stored in a stable manner.

According to the present invention, as described above, a memory cell is formed of one capacitor and two access transistors and the two access transistors are respectively connected to a sense bit line connected to a sense amplifier and connected to a restore bit line connected to a restore circuit. Therefore, a sense operation and a restore operation can be performed through separate and different paths and furthermore, a sense operation and a restore operation can be deactivated individually. Thus, row selection for a sense operation can be performed in a restore operation, enabling reduction in row access time for row selection to achieve high speed access.

In addition, by arranging active regions continuously extending in the column direction, arranging first and second bit lines in parallel to the active regions and disposing connection conductors for the first bit lines, connection conductors for the second bit lines and connection conductors for capacitors in the column direction in a prescribed sequence, memory cells can be arranged in high density to efficiently arrange sense bit lines and restore bit lines.

Moreover, active regions are arranged continuously extending in a, straight line form along the column direction and there is no need to provide regions for isolating the active regions in the column direction, thereby making it easy to micro-process the active regions.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device comprising:
a plurality of memory cells, arranged in rows and columns, each including a capacitor for storing information, and first and second access transistors coupled commonly to one electrode of said capacitor;
a plurality of first word lines, arranged corresponding to the respective memory cell rows, each coupled to the first access transistors of memory cells on a corresponding row for driving the first access transistors of the memory cells on the corresponding row into a conductive state when selected;
a plurality of second word lines, arranged corresponding to the memory cell rows, each coupled to the second access transistors of the memory cells on a corresponding row for driving the second access transistors of the memory cells on the corresponding row into a conductive state when selected;
a plurality of first bit lines, arranged corresponding to the memory cell columns, each coupled to the first access transistors of memory cells on a corresponding column for transferring data transmitted through a first access transistor of a selected memory cell on the corresponding column;
a plurality of second bit lines, arranged corresponding to the memory cell columns, each coupled to the second access transistors of the memory cells on a corresponding column for transferring write data to a selected memory cell on the corresponding column; and
a plurality of sense amplifiers, arranged corresponding to the plurality of first bit lines, each for sensing and amplifying data on a corresponding first bit line when activated; and
a plurality of restore circuits, arranged corresponding to the plurality of second bit lines and to the plurality of first sense amplifiers, each for latching at least amplified data by a corresponding first sense amplifier to drive a corresponding second bit line according to a latch signal therein when activated.

2. The semiconductor memory device according to claim 1, wherein
each of the restore circuits includes a latch gate receiving an output signal of a corresponding sense amplifier through a high input impedance and amplifying and latching the received output signal.

3. The semiconductor memory device according to claim 1, wherein
each of the restore circuits includes:
a transfer circuit arranged corresponding to a corresponding sense amplifier, and receiving an output signal of the corresponding sense amplifier through a high input impedance to transfer the output signal of the corresponding sense amplifier in response to a transfer instruction signal; and
a latch circuit for latching a transfer signal from said transfer circuit and driving a corresponding second bit line according to the latched transfer signal.

4. The semiconductor memory device according to claim 1, further comprising bit line initialization circuits, arranged corresponding to the first bit lines, each activated after a sense operation of a corresponding sense amplifier prior to a restore operation of a corresponding restore circuit and setting a voltage on a corresponding first bit line to a prescribed voltage when activated.

5. The semiconductor memory device according to claim 1, wherein
each of the sense amplifiers includes an amplification circuit receiving a potential on a corresponding first bit line through a high input impedance and amplifying a received potential to output an amplified data to a corresponding restore circuit.

6. The semiconductor memory device according to claim 1, further comprising a row select circuit for driving a first word line and a second word line to a selected state at different timings in accordance with an applied address signal.

7. The semiconductor memory device according to claim 1, wherein
each of the restore circuits includes:
a transfer gate rendered conductive for a prescribed period while the restore circuit is active, for transferring an output signal of the corresponding sense amplifier; and
a latch circuit for latching a signal transferred through said transfer gate, and
said row select circuit deactivates a second word line in a selected state prior to activation of said transfer gate.

8. The semiconductor memory device according to claim 1, further comprising second bit line initialization circuits arranged corresponding to the second bit lines, each for setting a corresponding second bit line to a prescribed voltage when activated.

9. The semiconductor memory device according to claim 1, further comprising a read column select gate arranged corresponding to each of the sense amplifiers, and rendered conductive according to a column select signal for transmitting an output signal of a corresponding sense amplifier onto an internal data line when conductive, wherein
each of the sense amplifiers has a sense output node electrically isolated from a latch node of a corresponding restore circuit.

10. The semiconductor memory device according to claim 1, further comprising a write column select gate arranged corresponding to each of the restore circuits and rendered conductive in response to a column select signal, for transmitting data on an internal data line to a latch node of a corresponding restore circuit when conductive.

11. The semiconductor memory device according to claim 1, wherein
each of the sense amplifiers includes:
a differential stage formed of first and second insulated gate transistors having gates respectively coupled to a corresponding first bit line and to a reference bit line and differentially amplifying potentials on said corresponding first bit line and said reference bit line; and
a load circuit stage coupled to said differential stage and amplifying and latching an output signal of said differential stage when activated.

12. The semiconductor memory device according to claim 1, wherein
each of the sense amplifiers outputs complementary signals, and
each of the restore circuits includes:
a differential stage receiving complementary output signals of a corresponding sense amplifier at gates of high input impedance to differentially amplify the complementary output signals; and
a latch circuit for amplifying and latching output signals of said differential stage.

13. The semiconductor memory device according to claim 1, wherein
the first and second bit lines are arranged in a folded bit line configuration.

14. The semiconductor memory device according to claim 1, wherein
the first and second bit lines are arranged on one side of corresponding sense amplifiers and corresponding restore circuits in parallel to each other,
each of the sense amplifiers includes a differential amplification circuit, having a first node coupled to a corresponding first bit line and a second node, for amplifying differentially voltages of the first and second nodes when activated, and
said semiconductor memory device further comprises:
a first initialization transistor, arranged to each of the first bit lines, for setting a corresponding first bit line and the first node of a corresponding sense amplifier to a prescribed voltage level when activated; and
a second initialization transistor, arranged corresponding to each of the second nodes of the sense amplifier, for setting a corresponding second node to a prescribed voltage level when conductive, and
each of the restore circuits receives complementary output signals of a corresponding sense amplifier to drive a corresponding second bit line arranged on said one side.

15. The semiconductor memory device according to claim 1, wherein
each of the memory cells are arranged such that one bit data is stored by memory cells storing data complementary to each other.

16. A semiconductor memory device comprising:
a plurality of active regions each having a prescribed width and arranged continuously extending in a column direction;
a plurality of first bit lines arranged in parallel to the active regions;
a plurality of second bit lines arranged in parallel to said active regions, the first bit lines and the second bit lines being arranged in a prescribed sequence in a row direction in a two-dimensional layout;
a plurality of first word lines arranged in a direction intersecting with said active regions;
a plurality of second word lines arranged in a direction intersecting with the active regions and in a prescribed sequence with said plurality of said first word lines;
a plurality of first connection conductors arranged in said column direction at prescribed intervals in correspondence to said active regions, for electrically coupling corresponding active regions to corresponding first bit lines;
a plurality of second connection conductors arranged in said column direction at prescribed intervals in correspondence to said active regions, and electrically coupling corresponding active regions with corresponding second bit lines; and
a plurality of memory cell capacitors, each having a storage electrode conductors arranged corresponding to the active region between the first conductor and the second conductor in the column direction, for electrically coupling to the corresponding active regions, the storage electrode conductor forming a part of a storage node storing data of a memory cell,
in each of said active regions, a first access transistor being formed in a region of intersection with a first word line, and a second access transistor being formed in a region of intersection with a second word line, and
each of the memory cells being formed of the first and second access transistors and a capacitor having the storage electrode conductor arranged between said first and second transistors.

17. The semiconductor memory device according to claim 16, wherein
a pitch between the first bit lines and a pitch between the second bit lines are equal to a pitch between word lines including the first and second word lines, the pitch indicating an interval between adjacent lines.

18. The semiconductor memory device according to claim 16, wherein
the first and second bit lines are made of conductor interconnection lines formed in interconnection layers different from each other, and
a pitch between the first bit lines and a pitch between the second bit lines are larger than a pitch between word lines including the first and second word lines, the pitch indicating an interval between adjacent lines.
